(19) United States
(12) Patent Application Publication
(10) Pub. No.: US 2026/0254397 A1
(43) Pub. Date: Aug. 27, 2026

(54) SYSTEMS AND METHODS FOR MULTISOURCE THERMOPHOTOVOLTAIC ENERGY CONVERSION

(71) Applicant: Oqab Dietrich Induction Inc., Kitchener (CA)

(72) Inventors: Nima Talebzadeh, Kitchener (CA); Paul G. O’Brien, Kitchener (CA); George B. Dietrich, Kitchener (CA); Haroon B. Oqab, Kitchener (CA)

(21) Appl. No.: 19/491,201

(22) PCT Filed: May 28, 2024
(86) PCT No.: PCT/CA2024/050709

§ 371 Date: Dec. 8, 2025

Related U.S. Application Data
(60) Provisional application No. 63/507,076, filed on Jun. 8, 2023.

(51) Int. Cl. H02S 10/30; H02J 50/00; H02J 50/20; H02J 50/30; H02S 40/22; H02S 40/38

(52) U.S. Cl. CPC H02S 10/30; H02J 50/005; H02J 50/20; H02J 50/30; H02S 40/22; H02S 40/38

(57) ABSTRACT

Provided herein are systems and methods for a multisource capable thermophotovoltaic (TPV) system. The TPV system includes an absorber that receives directed energy in the form of electromagnetic radiation from at least a primary source and converts the electromagnetic radiation to thermal energy, an emitter, thermally coupled to the absorber, wherein the emitter receives the thermal energy from the absorber and radiates the thermal energy, and a photovoltaic cell which receives the thermal energy from the emitter and converts the thermal energy to electric power. The absorber may receive energy from at least a second source providing a combination of two or more power generation technologies to obtain efficiencies higher than what could be obtained by identical sources individually. Using multiple sources also provides the capability to extend the duration of available electric power to a load and to control the output power in response to the variable loads.

### TECHNICAL FIELD

The embodiments disclosed herein relate to wireless energy production and distribution and, in particular, to systems and methods for converting directed energy or beamed power into electric power.

### INTRODUCTION

Wireless power transmission has gained popularity for both terrestrial and aerospace applications, primarily driven by the escalating costs associated with transporting conventional fuels for satellites, drones, and other aerospace systems. For example, drones are often powered by batteries, however, batteries are characterized by relatively low power densities, and they increase the overall weight of flying objects. Thermophotovoltaic (TPV) technology, with impressive system efficiencies reaching approximately 50%, presents a promising avenue for power generation by converting heat from any high-temperature source into electric power. TPV technology has emerged as a key player in clean energy storage.

TPV systems are lightweight, have no moving components, and are more efficient than diesel or gasoline engines. However, current TPV systems have low efficiencies relative to the maximum theoretical efficiency.

The efficiency of TPV systems increases as the temperature of their emitter increases, however the temperature of the emitter is also limiting for the power output and efficiency of the system. Furthermore, it is difficult to control the output power from a TPV system powered by a variable source of thermal energy, for example, the power output from solar TPV systems depends on the availability of the solar irradiance.

Using multiple sources of thermal energy, in a multisource TPV system, has the potential to increase the efficiency of TPV systems and to generate constant power when using thermal sources that provide variable input power. A multisource TPV system may increase the input of thermal energy as additional sources of thermal energy may provide energy during periods when lower amounts of power are provided by the primary source. Using multiple power sources provides opportunities to optimize the TPV system performance from power output, efficiency, and economic standpoints.

However, despite the benefits of multisource TPV systems limited work has been done in this area. Hussain et. al. investigated a hybrid solar TPV system that could simultaneously be powered by biomass fuels and concentrated solar energy. This TPV system was designed for non-intermittent operation and different climates and geographical conditions. They proposed three different configurations for the hybrid STPV. The same group also reported on a TPV system designed to achieve hybrid solar-biomass to power conversion with a high solar fraction and an economic appraisal of hybrid solar-biomass TPV power generators. However, to date, a comprehensive analysis on the power output and conversion efficiencies of multisource TPV systems has yet to be reported.

Accordingly, there is a need for new and improved multisource TPV systems which enable multiple sources of thermal energy to efficiently act as inputs to a single TPV system.

### SUMMARY

Provided herein is a multisource-capable thermophotovoltaic (TPV) system for converting electromagnetic energy to electric power, the system comprising an absorber that receives directed energy in the form of electromagnetic radiation from at least a primary source and converts the electromagnetic radiation to thermal energy, an emitter, thermally coupled to the absorber, wherein the emitter receives the thermal energy from the absorber and radiates the thermal energy, and a photovoltaic cell which receives the thermal energy from the emitter and converts the thermal energy to electric power.

The directed energy may be electromagnetic waves over a broad spectrum, including wavelengths from the X-ray to radio waves.

The absorber may receive energy from at least a secondary source.

The absorber may receive heat from the at least a secondary source.

The directed energy and the heat may be received simultaneously to heat the absorber and the emitter within the TPV system.

The absorber may receive directed energy from at least two sources.

The at least a secondary source may provide energy from one of fuel combustion, concentrated solar irradiance, waste heat, and heat from nuclear sources.

A temperature of the thermally coupled absorber and emitter is greater when heated by multiple sources than the temperature of the thermally coupled absorber and emitter when heated by each of the multiple sources individually.

The PV cell may directly receive electromagnetic radiation from the primary source and the emitter may receive energy from the at least one secondary source.

The energy of the at least one secondary source may be one of fuel combustion, concentrated solar irradiance, waste heat, heat from nuclear sources, and another power beam.

The absorber and the emitter may be connected to a thermal battery.

The TPV system may further comprise an optical cavity to concentrate electromagnetic radiation.

The optical cavity may have an oblate ellipsoid shape.

The optical cavity may have an oblate hemispheroid shape.

The TPV system may further comprise an optical filter.

Provided herein is a method of converting electromagnetic radiation to electric power, the method comprising receiving, by an absorber, directed energy in the form of electromagnetic radiation from at least a primary source, converting the electromagnetic radiation to thermal energy, by the absorber, receiving, by an emitter thermally coupled to the absorber, the thermal energy, radiating the thermal energy, by the emitter, receiving the thermal energy by a photovoltaic cell, and converting the thermal energy to electric power by the photovoltaic cell.

The absorber may receive energy from at least a secondary source.

The absorber may receive heat from the at least a secondary source.

The directed energy and the heat may be received simultaneously to heat the absorber and the emitter within the TPV system.

A temperature of the thermally coupled absorber and emitter is greater when heated by multiple sources than the temperature of the thermally coupled absorber and emitter when heated by each of the multiple sources individually.

Other aspects and features will become apparent to those ordinarily skilled in the art, upon review of the following description of some exemplary embodiments.

### BRIEF DESCRIPTION OF THE DRAWINGS

The drawings included herewith are for illustrating various examples of articles, methods, and apparatuses of the present specification. In the drawings:

FIG. 1 is a block diagram of a thermophotovoltaic cell receiving energy from a thermal emitter, showing the four pathways of photons;

FIG. 2A is a block diagram of a single wireless power beam as the source of energy for a TPV power generator;

FIG. 2B is a block diagram of a wireless power beam and waste heat as sources of energy for a TPV power generator;

FIG. 2C is a block diagram of a wireless power beam and concentrated solar irradiance as sources of energy for a TPV power generator;

FIG. 2D is a block diagram of a wireless power beam and combustion as sources of energy for a TPV power generator;

FIG. 2E is a block diagram of a wireless power beam, waste heat, and solar irradiance as sources of energy for a TPV power generator;

FIG. 2F is a block diagram of a wireless power beam, waste heat, and combustion as sources of energy for a TPV power generator;

FIG. 2G is a block diagram of a wireless power beam, solar irradiance, and combustion as sources of energy for a TPV power generator;

FIG. 2H is a block diagram of a wireless power beam, waste heat, solar irradiance, and combustion as sources of energy for a TPV power generator;

FIG. 3 is a chart of the various iterations of FIGS. 2A-2H shown together;

FIG. 4A is a schematic diagram of a TPV system having an oblate hemispheroidal optical cavity, according to an embodiment;

FIG. 4B is a schematic diagram of a TPV system having an oblate ellipsoidal optical cavity, according to an embodiment;

FIG. 5 is a schematic diagram of a TPV system having an ellipsoid electromagnetic concentrator as well as two sources of energy, an electromagnetic beam and a combustion chamber, according to an embodiment;

FIG. 6 is schematic diagram of a TPV system with a Cassegrain solar concentrator and an ellipsoid optical cavity, according to an embodiment;

FIG. 7 is a schematic diagram of a TPV system with a thermal storage capacity, according to an embodiment;

FIGS. 8A-C are graphs of experimental results showing efficiency and output power for a TPV system with various radii of an emitter; according to an embodiment;

FIGS. 9A-C are graphs of experimental results showing efficiency and output power for a TPV system with various radii of an emitter, and the emitter representing a blackbody; according to an embodiment;

FIG. 10 are graphs showing the efficiency and output power for a TPV system as a function of the radius of a blackbody emitter with input power of 1500 W, according to an embodiment;

FIG. 11 is graphs showing efficiency and power of a TPV system as a function of input laser power for a case of rₗₐₛₑᵣ=5 cm, attenuation coefficient=92.5%, 1 Km vertical distance between the laser power and absorber, η_{cav.}=95%, laser wavelength of λ=1060 nm, according to an embodiment;

FIG. 12 is graphs showing efficiency and power of a TPV system as a function of input laser power for a case of rₗₐₛₑᵣ=10 cm, attenuation coefficient=92.5%, 1 Km vertical distance between the laser power and absorber, η_{cav.}=95%, laser wavelength of λ=1060 nm, according to an embodiment;

FIG. 13 is graphs showing the effect of adding a secondary source of energy, according to an embodiment;

FIGS. 14A-14F are graphs showing A) power output from the TPV system (Pₒᵤₜ₍₁₊₂₎) when the input power is simultaneously supplied by sources 1 and 2 (P₁₊₂), B) the increase in the power output from the TPV system when it is simultaneously powered by sources 1 and 2 (Pₒᵤₜ₍₁₊₂₎) as compared to when it is powered solely by source 1 Pₒᵤₜ₍₁₎, C) the sum of the power output from the TPV system when it is powered solely by source 1 (Pₒᵤₜ₍₁₎) and when it is powered solely by source 2 (Pₒᵤₜ₍₂₎), and comparisons of the power output from the TPV system when it is powered solely by source 1 (Pₒᵤₜ₍₁₎), when it powered solely by source 2 (Pₒᵤₜ₍₂₎), when it is powered by sources 1 and 2 simultaneously (Pₒᵤₜ₍₁₊₂₎), and the sum of the output power when the TPV system is powered solely by source 1 and solely by source 2 (Pₒᵤₜ₍₁₎+Pₒᵤₜ₍₂₎) for the case when the power received from source 1 are D) 20, E) 40, and F) 100 W/cm², according to an embodiment;

FIGS. 15A and 15B are graphs of A) total system efficiency and B0 efficiency increase for primary sources of energy with various secondary sources of energy, according to an embodiment;

FIGS. 16A and 16B is graphs showing output ratio as a function of the additional power provided by a secondary source, according to an embodiment;

FIG. 17 is a graph of efficiency ratios for primary and secondary energy sources, according to an embodiment;

FIG. 18 is a graph showing the relative increase in the TPV system efficiency when a TPV system is powered by two sources simultaneously as compared to powered by each sources individually, according to an embodiment;

FIGS. 19A and 19B are graphs showing A) blackbody emissive power for Pᵢₙ₍₁₎=Pᵢₙ₍₂₎=1 W/cm2, Pᵢₙ₍₁₎+Pᵢₙ₍₂₎, and Pᵢₙ₍₁₊₂₎ and B) a closer view of the in-band region showing the in-band powers when the Pᵢₙ₍₁₎=Pᵢₙ₍₂₎=1 W/cm2, according to an embodiment;

FIGS. 20A and 20B are graphs showing A) blackbody emissive power for Pᵢₙ₍₁₎=Pᵢₙ₍₂₎=5 W/cm2, Pᵢₙ₍₁₎+Pᵢₙ₍₂₎, and Pᵢₙ₍₁₊₂₎ and B) a closer view of the in-band region (1.72 um) showing the in-band powers when the Pᵢₙ₍₁₎=Pᵢₙ₍₂₎=5 W/cm2; according to an embodiment;

FIG. 21 is a graph showing the net in-band power delivered to a GaSb PV cell when the in-band power of the primary source applied to the system (P_{inband(1)}) is subtracted from the total in-band power when both sources are applied simultaneously (P_{inband(1+2)}) as a function of the secondary power input (Pᵢₙ₍₂₎), for six sample examples of primary/initial input power sources, according to an embodiment;

FIG. 22 is a graph showing the net in-band power delivered to a GaSb PV cell when the in-band power of the primary source applied to the system (P_{inband(1)}) is subtracted from the total in-band power when both sources are applied simultaneously (P_{inband(1+2)}) as a function of the summation of the primary and secondary input power applied simultaneously (Pᵢₙ₍₁₊₂₎), for six sample examples of primary/initial input power sources, according to an embodiment;

FIG. 23 is a graph showing an in-band power ratio as a result of adding the secondary source over the in-band power coming from only the primary source, as a function of the summation of both input power applied simultaneously, according to an embodiment;

FIG. 24 is a graph showing a ratio of the in-band power as a result of adding the secondary source, over the in-band power when only primary source is applied as a function of the ratio of the secondary source to primary source, according to an embodiment;

FIG. 25 is a graph showing a net in-band power delivered to a GaSb PV cell when the output in-band power of the primary source applied to the system (P_{inband(1)}) is subtracted from the total output in-band power and both sources are applied simultaneously (P_{inband(1+2)}) as a function of the final temperature of the emitter when both sources are applied simultaneously (T_{final}), according to an embodiment;

FIG. 26 is a graph showing a net in-band power delivered to a GaSb PV cell when the output in-band power of the primary source applied to the system (P_{inband(1)}) is subtracted from the total output in-band power and both sources are applied simultaneously (P_{inband(1+2)}) as a function of the temperature of the emitter when the secondary source is applied (T₂), according to an embodiment;

FIG. 27 is a graph showing an in-band power ratio as a result of adding the secondary source as a function of the final temperature of the emitter (the temperature from the secondary source is added to the primary temperature), according to an embodiment;

FIGS. 28A-C are heatmap graphs showing A) the sum of the output power from a TPV system when it is powered by two sources individually (P_{out (1)}+P_{out (2)}), B) the output power from a TPV system when it is simultaneously powered by two sources (P_{out (1+2)}), C) the power enhancement (P_{out (1+2)}/(P_{out (1)}+Pₒᵤₜ₍₂₎) is achieved by powering the TPV system with two power sources simultaneously as compared to the power generated when the power sources are used individually, with an accompanying legend, according to an embodiment;

FIG. 29 is a picture of a sample set-up of a multisource TPV system, according to an embodiment;

FIG. 30 is a graph with outer pillars representing the total input power from a first source and a second source and the inner pillars representing the total output power from a multisource TPV system, according to an embodiment;

FIG. 31 is a flow diagram of a method of using a multisource-capable TPV system, according to an embodiment.

### DETAILED DESCRIPTION

Various apparatuses or processes will be described below to provide an example of each claimed embodiment. No embodiment described below limits any claimed embodiment and any claimed embodiment may cover processes or apparatuses that differ from those described below. The claimed embodiments are not limited to apparatuses or processes having all of the features of any one apparatus or process described below or to features common to multiple or all of the apparatuses described below.

Herein the terms “beamed power” and “directed energy” may be used interchangeably to refer to electromagnetic radiation. That is, where beamed power is described the source of energy could also be directed energy and vice versa.

Provided herein are multisource thermophotovoltaic (TPV) systems outputting electric power converted from thermal energy from multiple different sources.

As discussed above, multisource TPV systems have the potential to achieve higher efficiencies compared to traditional single-source TPV systems.

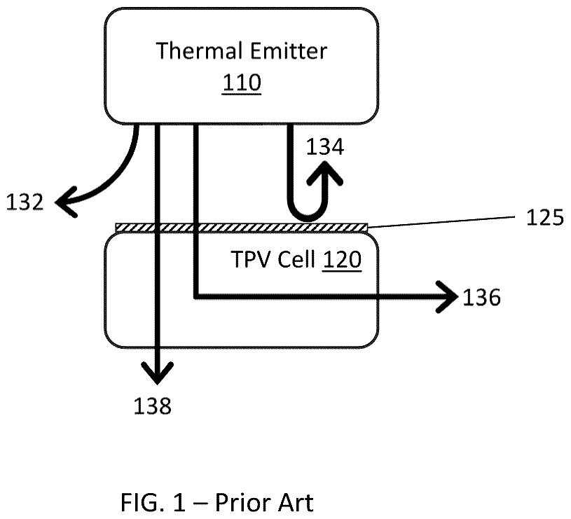

The main components of a TPV system are an emitter and a PV cell. The mechanism of a PV cell is shown in FIG. 1. A thermal emitter 110 emits thermal energy toward a PV cell 120. The PV cell 120 includes an optical filter 125 on a surface which receives photons from the thermal emitter 110. The energy of the photons is greater than the bandgap of the PV cell in order for excess energy to be converted to thermal energy to be used by the PV cell. The bandgap is the energy an excited charge carrier needs to receive from an absorbed photon to generate current and output power in a photovoltaic cell (PV). For example, a PV cell made of GaSb has a bandgap of 0.72 eV. The bandgap is a threshold energy. “In-band” photons have wavelengths low enough such that their energy is higher than the bandgap value and can be absorbed and converted to electrical energy by the PV cell.

Herein a “photovoltaic cell” (PV cell) often refers to a thermophotovoltaic cell (TPV cell) as the TPV systems discussed convert thermal energy to electric power through a PV cell. However, in some embodiments a PV cell which is converting energy other than thermal energy to electric power may be used along with a thermophotovoltaic cell converting thermal energy to electric power. It is to be understood that when PV cell is explicitly converting thermal energy to electric power the PV cell is a TPV cell, and when the PV cell is not explicitly converting thermal energy to electric power the PV cell may not be TPV cell.

The photons emitted by the thermal emitter have four possible outcomes. A portion of the photons are lost due to non-unity factor viewing (arrow 132). A portion of the photons are reflected back to the thermal emitter off of the optical filter as recycled photons (arrow 134). A portion of the photons are received within the PV cell 120 but lost through thermalization (arrow 136). And a final portion of the photons are received by the PV cell 120 and converted into an electric output (arrow 138). As not all photons are absorbed by the PV cell, nor are all photons absorbed by the cell converted to electric power, optimization of input of photons and the performance of the PV cell is important.

TPV systems achieve higher output power by simultaneously receiving power from multiple sources. A power output that is simultaneously powered by a power source “1” and a power source “2” is typically greater than the power output from the same TPV system when it is powered by only power source “1” or only power source “2”.

For example, combining solar and thermal energy to power a TPV system can lead to a higher energy conversion efficiency as compared to when the same TPV system is powered by the same solar and thermal energy sources separately at different times.

“Power beaming” is the transmission of energy using a directed electromagnetic beam. Lasers and microwaves have primarily been investigated for power beaming, although electromagnetic radiation at other wavelengths can be used.

Atmospheric attenuation can severely decrease the transmitted beam power, especially over the electromagnetic wavelength range used in laser power transmission. Transferring the electromagnetic wave in the form of a periodically pulsed power beam may alleviate atmospheric attenuation. Using electromagnetic wavelengths for which the atmosphere is transparent, or has a low absorption coefficient, also mitigates atmospheric attenuation.

### Receivers in Power Beaming Energy Transfer

In general, electromagnetic radiation power beaming is based on two types of electromagnetic radiation: microwave/RF power, and light/laser power.

### Microwave/RF

There are several prototypes that demonstrate terrestrial microwave power beaming at distances >1 km. A 4 m2 rectenna receiver has produced 1.6 kW output power in the X-band and a 73% RF-to-DC conversion efficiency was achieved. The transmitter had a 5.4 m diameter.

A 2.2 m airship drone has been developed which is powered by X-band microwaves (10 GHz). The airship was a precursor for a large-scale drone for cargo transportation applications. A total of 32 rectenna array sheets were placed on the airship. The voltage and power requirement for the airship was 6V and 8 W, respectively. The rectenna array system was positioned 6 meters away from the horn antenna and an overall efficiency of 3-4% was achieved. Output power was measured across a range of frequencies from 7 to 13 GHz, with the maximum output power varying significantly depending on the frequency. At 7.2 GHz, the system produced a maximum output power of 10.2 W, while at 10.2 GHz, the maximum output power was 8.0 W.

The. A system has been developed for a spaced-based solar power station (SSPS) in China with an array of PV cells to harvest and convert the solar irradiance to electricity. The electric power is used to transmit a microwave power beam to rectenna arrays located 100 m away. DC-to-DC power conversion efficiencies of 16.2% and overall efficiencies of 4.3%, respectively, were achieved.

In collaboration with Japan Space Systems (J-spacesystems), Japan Aerospace Exploration Agency (JAXA) carried out a research and development initiative aimed at creating wireless power transmission technology for space solar power stations (SSPS) with a particular emphasis on highly accurate microwave beam-pointing control. The transmission frequency, transmission power, receiving power, and transmission distance were 5.8 GHz, 1.8 kW, 320-340 W, and 55 m, respectively.

### Light/Laser

There are photovoltaic laser power converters (PVLPCs) for power-by-light. For example, single-photovoltaic laser power converter (S-PVLPC) with an efficiency of 68.9 were presented in 2021. Similarly, an S-PVLPC system with a peak efficiency of 58% was demonstrated in 2018. The maximum power delivered by the S-PVLPC was 0.7 W.

There is an S-PVLPC with input power density, operation wavelength, and system efficiency of 11.4 W/cm2, 858 nm, and 68.9%, respectively. The key reason for the improvements achieved in this work was a dielectric-silver back reflector integrated beneath the active layers of the photovoltaic cell.

The concept of harvesting the solar irradiance in outer space and sending it down to earth via laser power beaming at a wavelength of 1.6 μm exists. This concept could use a 10 kW IR laser and a lens 2.5 m in diameter to collimate the IR laser beam at GaSb (gallium antimony) PV cells. At the desired point of use, the lens array with IR PV cells converts the 10 kW IR beam at 40% efficiency to 4 kW of electric power.

There is being developed a space infrastructure to establish a laser-based wireless power grid in space. This infrastructure has the potential to enable the creation of an on-demand source in the near future.

### Multi-Fuel TPVs

There is a multi-fuel thermophotovoltaic generator that incorporates a recuperator. The TPV system uses conveniently available liquid hydrocarbon fuels.

There is a TPV system with the capability of using a variety of different liquid or gaseous fuels.

There is research on a TPV system capable of being powered by different hydrocarbon fuels.

There is TPV systems for personal power sources with multi-fuel capability.

### Multisource TPVs

There is a hybrid solar TPV system that could simultaneously be powered by biomass fuels and concentrated solar energy. The TPV system was designed for non-intermittent operation and different climates and geographical conditions. A similar TPV system exists for achieving high-solar-fraction hybrid solar-biomass power generation.

There is a hybrid TPV system capable of being powered by a combination of a fossil fuel burners that could be powered using different fuels and collected thermal energy (e.g. concentrated solar irradiance).

There is a hybrid thermophotovoltaic power driving system for an electric vehicle. This system combines heat from concentrated solar energy and heat energy from fuel combustion to power a TPV system.

A hybrid thermophotovoltaic system may be applicable for a wide range of radiation spectrum. A technology exists for converting electric power from various energy sources such as solar energy, combustion energy, waste heat source, and the like.

There is the concept of simultaneously using solar radiation and a combustion heat source.

### Advantages of Multisource TPV Systems

As described above, in multisource thermophotovoltaic (TPV) technology multiple heat sources are combined to improve the heat-to-electric power energy conversion efficiency. By powering TPV systems with additional heat sources that increase the temperature of the emitter, multisource TPV systems can achieve higher efficiencies than traditional TPV systems that use a lone heat source. For example, combining solar and thermal energy to power a TPV system can lead to a higher energy conversion efficiency as compared to when it is powered by the same solar and thermal energy sources separately. In summary, the advantages of a multisource TPV systems are as follows:
i) Enhanced System Reliability and Stability: Using multiple sources provides redundancy, if one source fails or its output fluctuates, the other sources can compensate, ensuring a more stable power output.
ii) Dynamic Load Balancing: Multiple sources can be dynamically managed to balance the load and prevent any single source from being overworked, which can extend the lifespan of the system components.
iii) Better Demand Response: Systems can respond more flexibly to demand peaks by adjusting the contribution of each source, potentially earning revenue from demand response programs.
iv) Flexibility in Fuel Choice and Availability: Multiple sources can utilize different types of fuels, such as solar, biomass, waste heat, and fossil fuels. This flexibility can be advantageous in different geographic locations and under varying conditions. Relying on diverse energy sources reduces dependency on a single fuel type, which can be critical during fuel shortages or price volatility.
v) Improved Heat Distribution: Multiple heat sources can distribute thermal energy more evenly across the TPV system, reducing hot spots and improving thermal management.
vi) Temperature Optimization: Different sources can be operated at different temperatures, allowing for better optimization of the TPV system's operating temperature range.
vii) Higher Power Density: Combining multiple sources can increase the overall power density, providing higher energy output from the same system footprint.
viii) Scalability and Modularity: Multisource TPV systems can be scaled up or down easily by adding or removing energy sources, making them suitable for a wide range of applications from small-scale residential to large-scale industrial. Furthermore, components can be modular, allowing for phased implementation and investment, spreading costs over time, and reducing upfront capital expenditure.
ix) Environmental Benefits: Multiple sources allow for the optimal use of available resources, reducing waste and improving overall sustainability.
x) Reduced Dependency on High-Cost Fuels: Using multiple sources can minimize reliance on expensive or volatile fuel markets, stabilizing the overall cost structure.

Briefly, the output of a TPV system varies based on two main system parameters: emission power from the surface of the emitter; and the temperature of the surface of the emitter. Experimental and numerical analysis of a multisource TPV system can be undertaken based on power and/or based on temperature.

### Power Based Example

Power emitted from the surface of an emitter by a primary source of energy varies from of Pᵢₙ₍₁₎=0 to 100 W/cm² of emitter area, and a secondary source of energy such as solar energy (or an electromagnetic beam) ranging from Pᵢₙ₍₂₎=0 to 100 W/cm² of emitter area is also considered. Results show that for small amounts of primary power, adding the secondary power significantly increases the system efficiency and output power density rates. For larger initial power sources the system efficiency still increases when secondary power is added, although to a lesser extent. For example, for an initial power source of 5 W/cm², providing input solar power (secondary source) at a rate of 5 W/cm², increases the output power by 420%. When the initial power source is 100 W/cm², providing input solar power (secondary source) at a rate of 100 W/cm² increases the system efficiency by 151%.

### Temperature Based Example

The temperature of the surface of the emitter powered by a primary energy source varies from Tᵢₙ₍₁₎=800 to 2200 K, and the temperature of the emitter changes as a result of applying a secondary source which varies from Tᵢₙ₍₂₎=0 to 1700 K. The limit of the final maximum temperature the surface of the emitter can reach is assumed to be T_{final}=2500 K (Final surface temperature varies from T_{final}=800 K to from T_{final}=2500K according to Tᵢₙ₍₁₎ and Tᵢₙ₍₂₎). The results show that for the small amounts of primary temperature of the emitter (Tᵢₙ₍₁₎) powered by the first source, adding secondary power in the form of solar radiation or beamed power to increase its surface temperature, significantly increases the in-band power rate. For larger initial source temperature the in-band energy still increases when secondary power is added, although to a lesser extent. For example, for an initial source temperature of Tᵢₙ₍₁₎=850 K, adding the secondary source and increasing the surface temperature by Tᵢₙ₍₂₎=150 K (T_{final}=1000 K), increases the in-band power by ~1000%. When the initial surface temperature is Tᵢₙ₍₁₎=2000 K, providing input solar power (secondary source) and increasing the surface temperature by Tᵢₙ₍ₛ₎=150 K (T_{final}=2150 K) increases the system efficiency by ~52%.

In implementations, multiple energy sources could be used in addition to the beamed power source to simultaneously power the TPV system. Other sources of energy could include, but are not limited to, solar irradiance, fuels, waste heat, and nuclear energy sources.

In one implementation, electromagnetic radiation powers a TPV system when the radiation is incident onto an absorber that is thermally coupled to an emitter. Radiation from the emitter is converted to electric power in a photovoltaic (PV) cell. In this instance the emitter may also be heated by other sources including heat from fuel combustion, waste heat, or solar radiation. The absorber may receive electromagnetic radiation over a broad spectrum, e.g., gamma rays to x-rays, to convert to heat for the TPV system.

In another implementation, electromagnetic radiation may be incident directly onto a PV cell within a TPV system. The PV cell receives radiation from the emitter within the PV cell at the same time it receives incident electromagnetic radiation. The emitter may be heated by one or more sources including heat from fuel combustion, waste heat, solar radiation, or from a second source of electromagnetic radiation.

In yet another implementation, the TPV system may include an optical cavity in one of various forms of ellipsoids and/or geometric equivalents to receive the beamed electromagnetic radiation. The shape and size of the optical cavity may be adjusted to support, tune and/or match the range of applications. An advantage of this system is the presence of two foci, one for emission, where the heat is directed, and one for conversion, which is kept as cool as possible.

In some implementations, one of the multiple sources of electromagnetic radiation may not be wireless, and instead may be from a source such as an optical cable or waveguide.

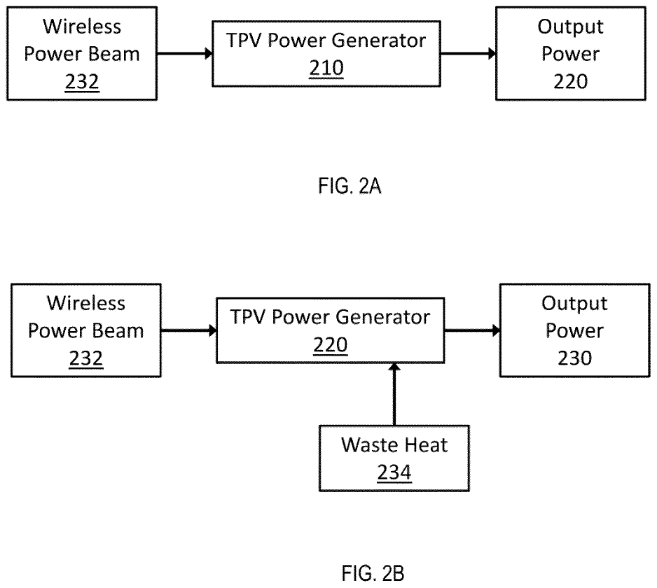

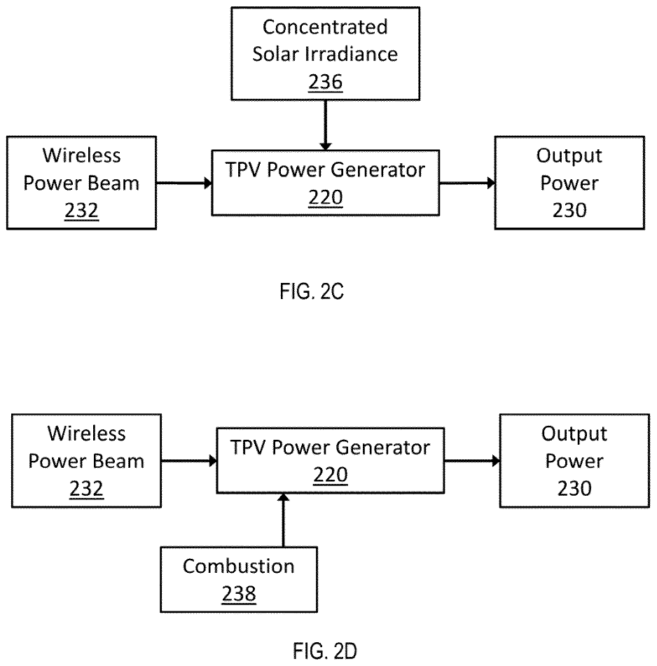

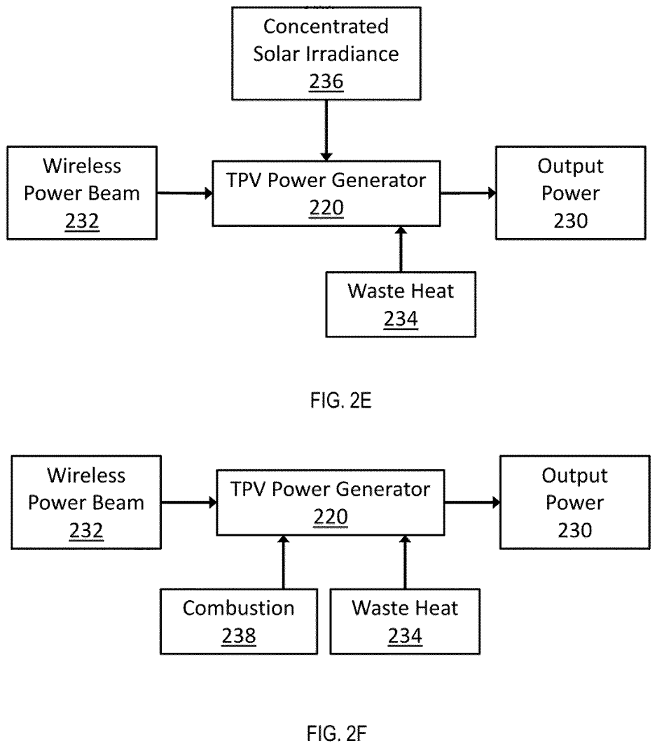

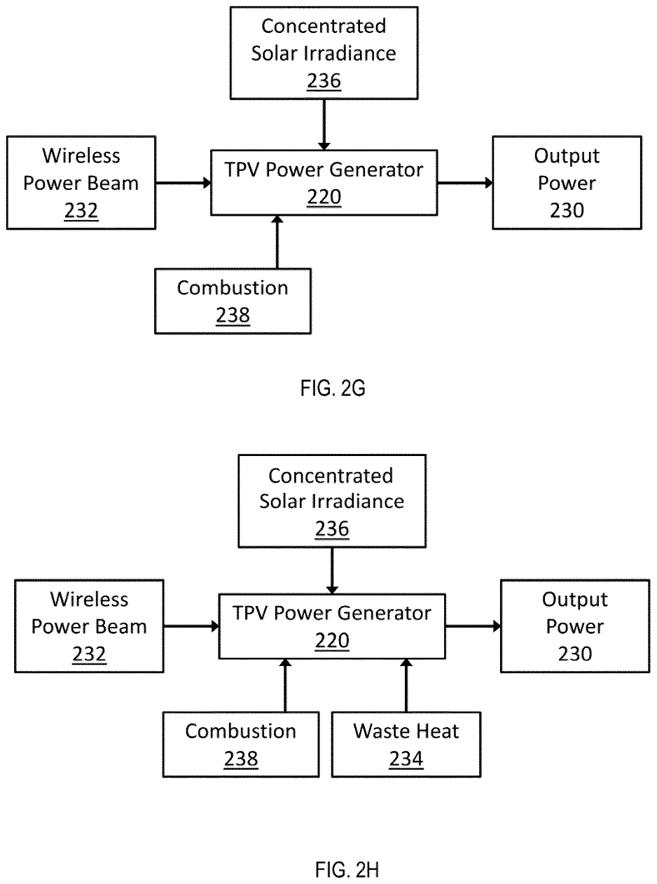

FIGS. 2A-2H are block diagrams showing various groups of sources for a TPV system. FIGS. 2A-2H all include a TPV power generator 210, which may be similar to the PV cell 120 of FIG. 1, and output power 220, which is output by the TPV power generator 210.

FIG. 2A shows a single wireless power beam 232 as the source of energy for the TPV power generator 210.

FIG. 2B shows both wireless power beam 232 and waste heat 234 as sources of energy for the TPV power generator 210.

FIG. 2C shows both wireless power beam 232 and concentrated solar irradiance 236 as sources of energy for the TPV power generator 210.

FIG. 2D shows both wireless power beam 232 and combustion 238 as sources of energy for the TPV power generator 210.

FIG. 2E shows wireless power beam 232, waste heat 234, and concentrated solar irradiance 236 as sources of energy for the TPV power generator 210.

FIG. 2F shows wireless power beam 232, waste heat 234, and combustion 238 as sources of energy for the TPV power generator 210.

FIG. 2G shows wireless power beam 232, concentrated solar irradiance 236, and combustion 238 as sources of energy for the TPV power generator 210.

FIG. 2H shows both wireless power beam 232, waste heat 234, concentrated solar irradiance 236, and combustion 238 as sources of energy for the TPV power generator 210.

The four different sources of energy for the TPV power generator 210 are meant as examples. In other embodiments, any number and type of electromagnetic energy sources may be used.

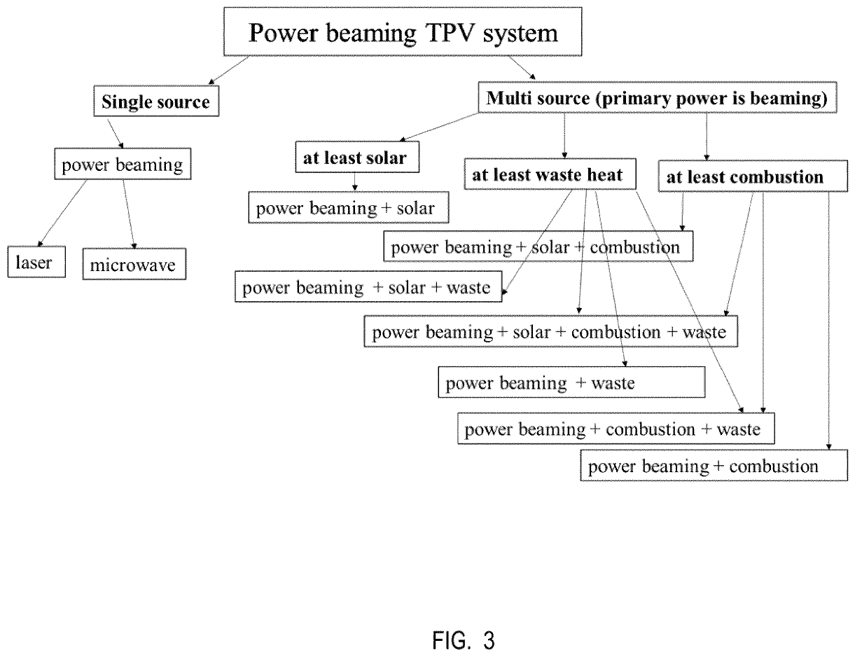

The various iterations of sources for TPV power generation are again shown in FIG. 3. FIG. 3 is also for illustrative purposes with the number and types of electromagnetic radiation being examples. The four energy sources of FIG. 3 are power beaming of laser or microwaves, solar, waste heat, and combustion. If the multi-source capable TPV system only uses a single source (e.g., the primary source) it is power beaming. The secondary sources are solar, waste heat, and combustion. In the example TPV system of FIG. 3, multisource energy can come from power beaming plus any one, any two, or all three of the secondary sources. In some embodiments, inductively coupled and/or magnetically coupled systems may be used as a source. In some embodiments, radiation photons from certain controlled nuclear reaction may be used as a source, including but not limited to gamma rays produced in a nuclear fusion reaction can be scintillated to produce high energy photons that can be harvested in the TPV system.

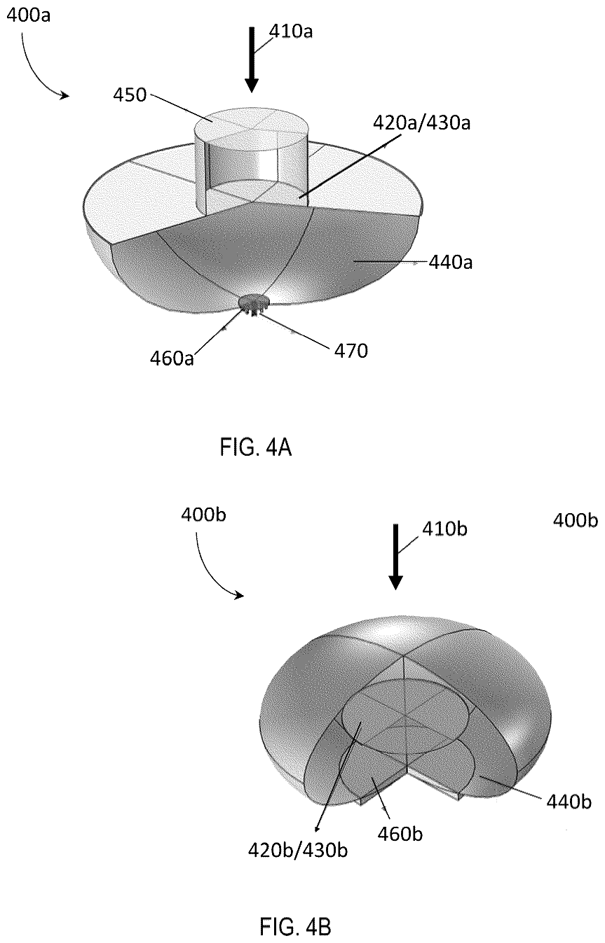

FIGS. 4-7 represent six example structures for a power beaming TPV system.

In FIG. 4A, the TPV system 400a includes a power beam 410a in the form of a concentrated electromagnetic wave is incident onto an absorber 420a which is thermally coupled to an emitter 430a. The absorber/emitter 420a/430a spans the foci area of an oblate hemispheroidal optical cavity 440 to maximize photon recycling and increase the temperature of the emitter to increase the system efficiency and output power density. The inner surface of the optical cavity is made up of a highly specular reflective coating in the infrared (IR) region of the electromagnetic spectrum (e.g., a coating of aluminum or gold). A selective heat mirror 450 matched with the incoming wavelength of the power beam 410a can be added on top of the emitter 430a to decrease the emission losses and increase the photon recycling. The emitter 430a directs thermal energy to the photovoltaic (PV) cell 460. The PV cell 460 may be a GaSb (gallium antimony) PV cell.

The TPV system 400a includes cooling fins 470.

Emission losses could also be decreased by using a spectrally selective absorber to absorb the incoming light while emitting limited amounts of radiation with wavelengths or directions that cannot be converted to electric power in the PV cell.

The TPV system 400b shown in FIG. 4b is similar to that shown in FIG. 4a, but with the optical cavity 440b in the shape of an oblate ellipsoid instead of an oblate hemisphere. In this structure the absorber 420b can also be a blackbody as the upward emission is reflected to the blackbody and recycled. A part of the top hemisphere is a transparent selective surface that allows incident solar radiation or an electromagnetic power beam 410b to pass while reflecting radiation emitted from the blackbody emitter 430b/absorber 420b. The blackbody emitter 430b emits thermal energy towards the PV cell 460b.

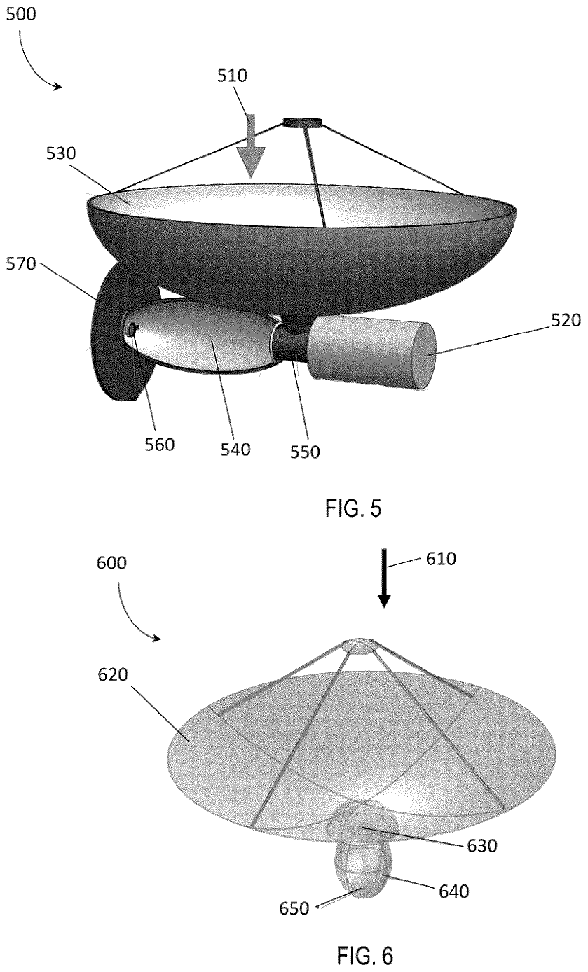

FIG. 5 shows a TPV system 500 wherein one of the heat sources originates from beamed power 510. The other heat source is transferred from a combustion chamber 520. The TPV system 500 comprises an ellipsoid electromagnetic wave concentrator 530. Thermal emission from the emitter 540 (which is located at a first focal point of the ellipsoid) is directed to a low-bandgap PV cell 560 (for example GaSb) which is located at the second focal point of the ellipsoid. The emitter 540 receives thermal energy from a multisource TPV 550 which receives energy from the beamed power 510 and the combustion chamber 520. The emitter 540 emits thermal energy to the PV cell 560. The TPV system 500 also includes radiative cooling 570 at the output of the PV cell 560.

FIG. 6 shows an example of a TPV system 600 with a receiver that accepts electromagnetic radiation 610. In this configuration the receiver is in the form of a Cassegrain solar concentrator 620 to focus the incoming electromagnetic radiation 610 (e.g. the incident power beam) onto the emitter/absorber 630. The emitter/absorber 630 is located on the foci of an optical cavity 640 with an oblate hemispheroid and prolate spheroid shape and the PV cell 650 is located at the lower focal point in the prolate spheroid which improves the conversion efficiency of the TPV system 600.

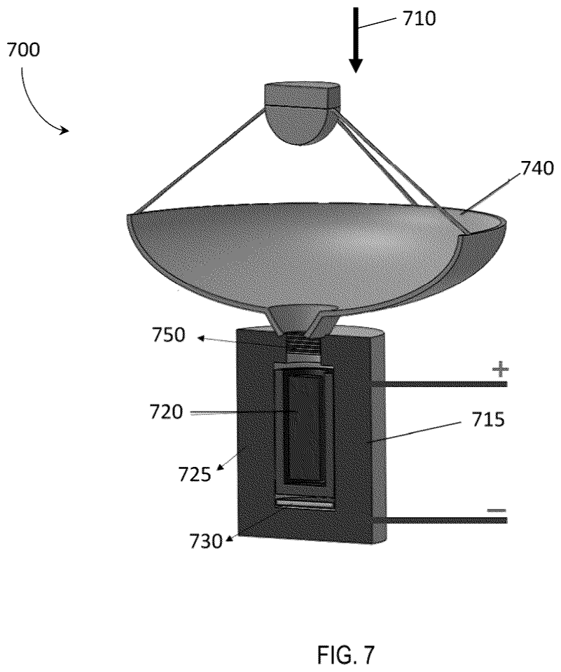

FIG. 7 shows another example of a TPV system 700 with a thermal energy storage capability to store the thermal heat in a chamber/media 720 (e.g., graphite blocks and/or molten silicon and/or molten salt, etc.) having thermal insulation 725. For electricity demand, the thermal storage can convert the electromagnetic radiation 710 into electricity 715 by the PV cell 730, and for heat/thermal energy demand the stored heat can be directly used (combined heat and power). The TPV system 700 also has a receiver 740 that accepts electromagnetic radiation. In this configuration the receiver is in the form of a Cassegrain solar concentrator to focus the incoming electromagnetic radiation 710 (e.g., the incident power beam) onto the storage chamber 720. The storage chamber may include an optical filter 750 (transparent selective surface) that allows incident solar radiation or an electromagnetic power beam to pass while reflecting radiation emitted from the storage material.

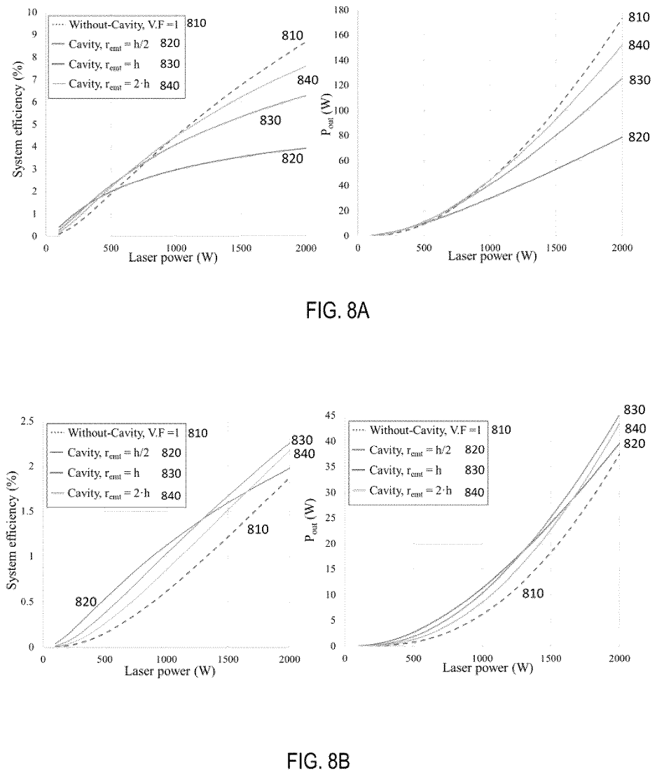

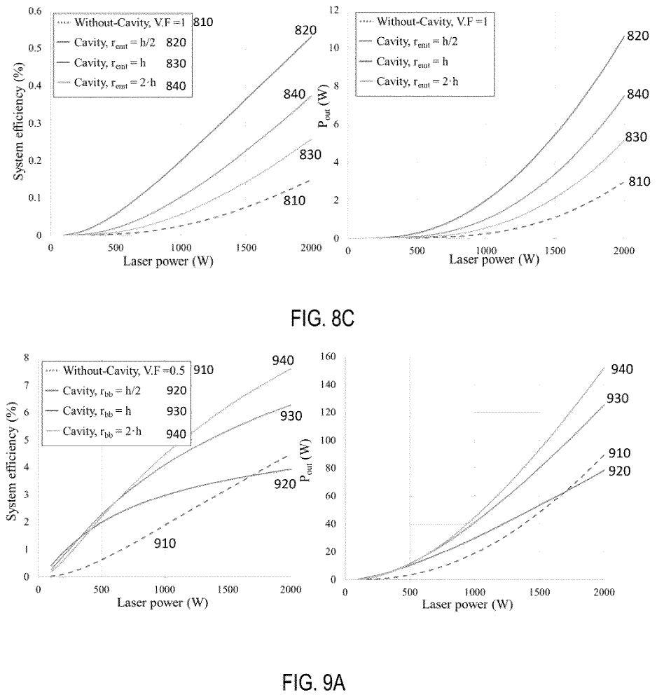

FIGS. 8A-28 represent experimental results illustrating the advantages of TPV systems with receivers that accept beamed power as a source of thermal energy.

FIGS. 8A through 8C show the efficiency and output power of four different TPV systems as a function of the incoming energy/power. A control TPV system is comprised of only an emitter and a PV cell and does not have an optical cavity. This TPV system is considered as a reference case to show the performance of the TPV system in the absence of a cavity, and is shown as a dashed line 810. For the reference case of FIGS. 8A to 8C the view factor (VF) is assumed to be one (this is achieved for the ideal case in which the PV cell and the emitter are parallel infinite planes and the emitter radiates only in the direction towards the PV cell).

The other three TPV systems in FIGS. 8A to 8C, represented by lines 820, 830, and 840 have the configuration shown in FIG. 4a. For the results shown in FIGS. 8A-C it is assumed the reflectivity of the internal walls of the semi-oblate ellipsoid is 100%. For the three cases the radius of the emitter is either rₑₘₜ=h/2 (line 820), rₑₘₜ=h (line 830), or rₑₘₜ=2·h (line 840), where rₑₘₜ is the radius of the emitter and h is the distance between the emitter and the PV cell. Furthermore, for all TPV systems considered in FIGS. 8A-C it is assumed the absorber has an ideal absorption and emission spectra such that all incident radiation is absorbed and no thermal radiation is emitted in directions external to the cavity. It is also assumed the radiation from the emitter has the spectra of a black body.

For the results shown in FIGS. 8A-C, rₑₘₜ=rₚᵥ=5, 10, and 20 cm, respectively. At rₑₘₜ=rₚᵥ=5 cm, the three TPV systems are less efficient than the control and do not produce as much power output (W) as the control. At rₑₘₜ=rₚᵥ=10 cm, the three TPV systems are slightly more efficient and more productive than the control. At rₑₘₜ=rₚᵥ=20 cm, the efficiency of all three TPV systems is better than the efficiency of the control, and the power output is greater.

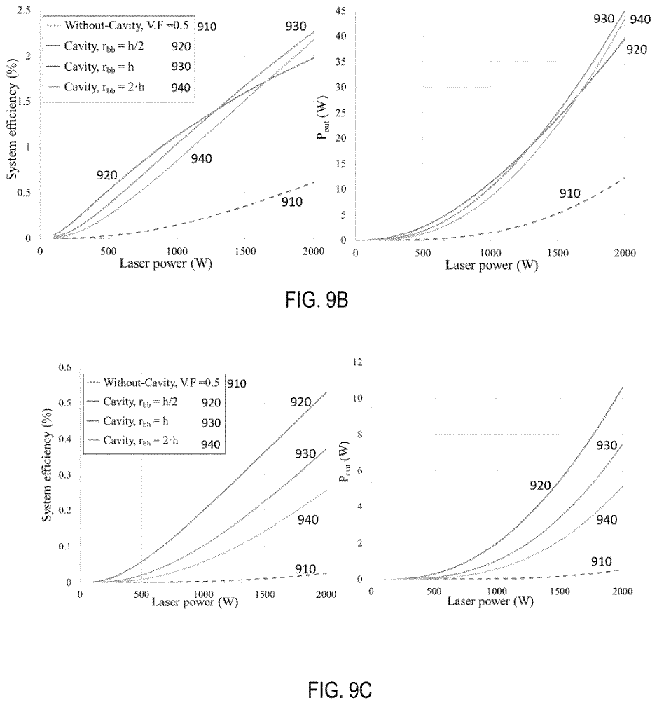

FIGS. 9A-C represent the same configuration of TPV system as FIG. 4b, in particular an ideal TPV system configuration, as shown in FIG. 4b, is assumed wherein all upwards emissions from the absorber/emitter are reflected and recycled. For the results shown in FIGS. 8A-8C it was assumed the absorber was ideal and that it did not emit any radiation while for the results shown in FIGS. 9A-9C it is assumed the absorber has the emittance spectra of a blackbody such that there is a maximum amount of radiative losses from the absorber. FIGS. 9A-C include a control TPV (line 910) with a view factor of 0.5, as well as three TPV systems (lines 920, 930, and 940). For the three cases the radius of the emitter is either rₑₘₜ=h/2 (line 920), rₑₘₜ=h (line 930), or rₑₘₜ=2·h (line 940), where rₑₘₜ is the radius of the emitter and h is the distance between the emitter and the PV cell.

For the results shown in FIGS. 9A-C, rₑₘₜ=rₚᵥ=5, 10, and 20 cm, respectively. At rₑₘₜ=rₚᵥ=5 cm, the three TPV systems are more efficient than the control and produce as more power output (W) than the control, with the exception of line 920 wherein the TPV is more efficient and produces more power only below 1500 W of laser power. At rₑₘₜ=rₚᵥ=10 cm, the three TPV systems are more efficient and more productive than the control. At rₑₘₜ=rₚᵥ=20 cm, the efficiency and power production of all three TPV systems is even better than the 10 cm iteration.

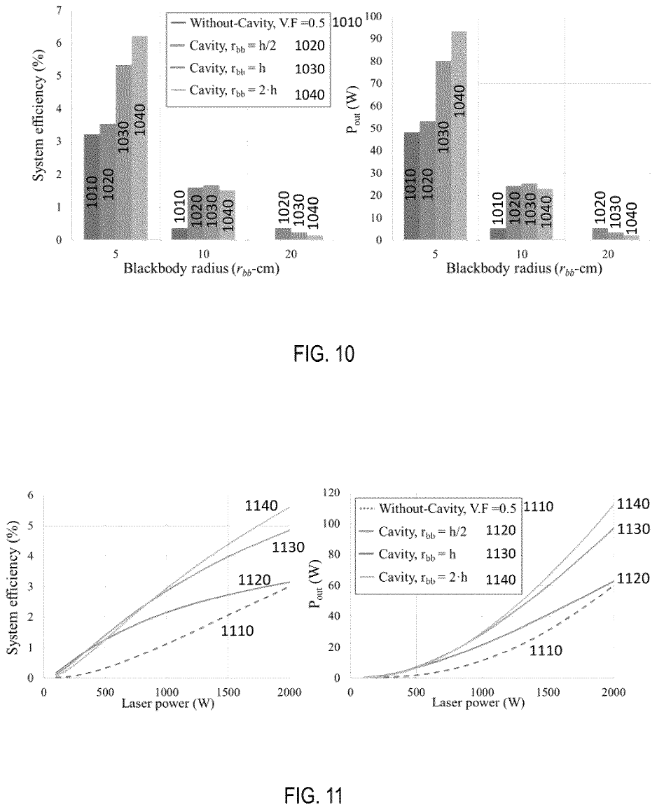

FIG. 10 shows the PV efficiency and output electric power (Pₒᵤₜ) as a function of the radius of a black body emitter (r_{bb}=rₚᵥ) when the input power is 1500 W. For all rₑₘₜ lengths (5 cm, 10 cm, and 20 cm), the system efficiency and power output are better than the control. The view factor (VF) is assumed to be 0.5. Line 1010 represents a configuration with no cavity. For the three test cases the radius of the emitter is either rₑₘₜ=h/2 (line 1020), rₑₘₜ=h (line 1030), or rₑₘₜ=2·h (line 1040), where rₑₘₜ is the radius of the emitter and h is the distance between the emitter and the PV cell.

FIG. 11 shows the system efficiency and electric power output for a TPV system powered by a laser with a wavelength of λ=1060 nm when there is a vertical distance of 1 km between the laser source and the TPV system. This distance of 1 km results in an atmospheric attenuation of 7.5% for clear sky and a laser beam divergence angle of 14% when the radius of the laser aperture is rₗₐₛₑᵣ=5 cm (which implies the radius of the blackbody absorber on the TPV system should be 5.7 cm to absorb the entire laser beam). Moreover, the reflectance of the internal surface of the optical cavity is assumed to be η_{cav.}=95% (which is comparable to that of an aluminum coating). The control without cavity is line 1110. For the three test cases the radius of the emitter is either rₑₘₜ=h/2 (line 1120), rₑₘₜ=h (line 1130), or rₑₘₜ=2·h (line 1140), where rₑₘₜ is the radius of the emitter and h is the distance between the emitter and the PV cell.

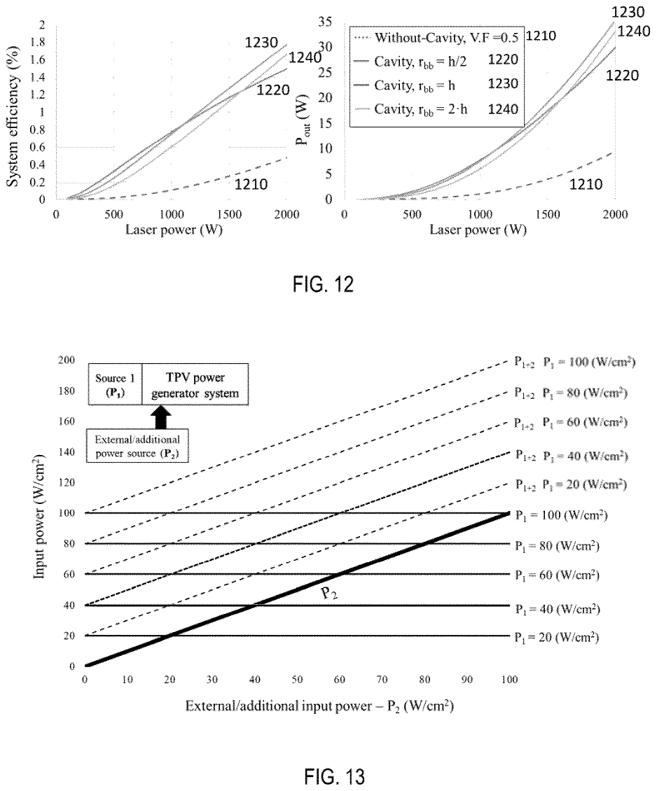

FIG. 12 shows the result similar to the assumptions in FIG. 11 except the radius of the laser aperture transmitter of rₗₐₛₑᵣ=10 cm which accommodates a beam divergence angle of 3%. The control without cavity is line 1210. For the three test cases the radius of the emitter is either rₑₘₜ=h/2 (line 1220), rₑₘₜ=h (line 1230), or rₑₘₜ=2·h (line 1240), where rₑₘₜ is the radius of the emitter and h is the distance between the emitter and the PV cell.

The results shown in FIGS. 13 through 18 are calculated for TPV systems under the assumptions that the emitter has the properties of a blackbody emitter (ε=1) and a GaSb PV cell. It is also assumed the view factor between the emitter and the PV cell is one (VF=1). Further, it is assumed the TPV systems are powered by either: a first power source (P₁) which is received in the form of electromagnetic radiation; or a second power source (P₂), which could be from a number of different sources including electromagnetic radiation, or heat from combusting fuels or from concentrated solar radiation, or waste-heat; or the TPV system could be powered by sources P₁ and P₂ simultaneously (denoted as P₁₊₂). Wherever the power is reported on a per area basis it is the area of the emitter that is being referred to.

For the results shown in FIG. 13 it is assumed that the initial power source, P₁, is constant (different values of P₁ that are considered are shown as the solid horizontal lines: P₁=20 W/cm²; 1402 P₁=40 W/cm²; P₁=60 W/cm²; P₁=80 W/cm²; and P₁=100 W/cm². The second source providing power to the TPV system, P₂, is assumed to vary from 0 to 100 W/cm² and the dashed lines shown in FIG. 13 show the sum of P₁ and P₂, or the total input power, which is denoted as P₁₊₂.

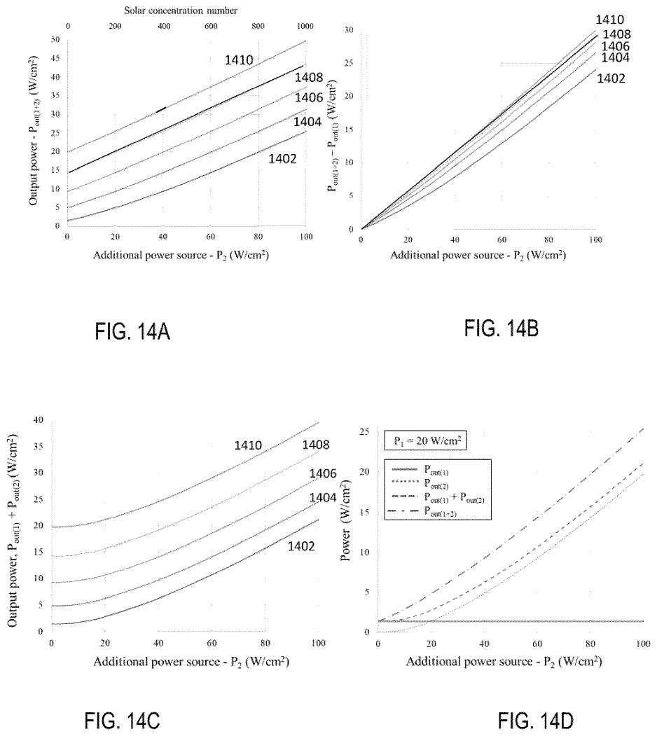

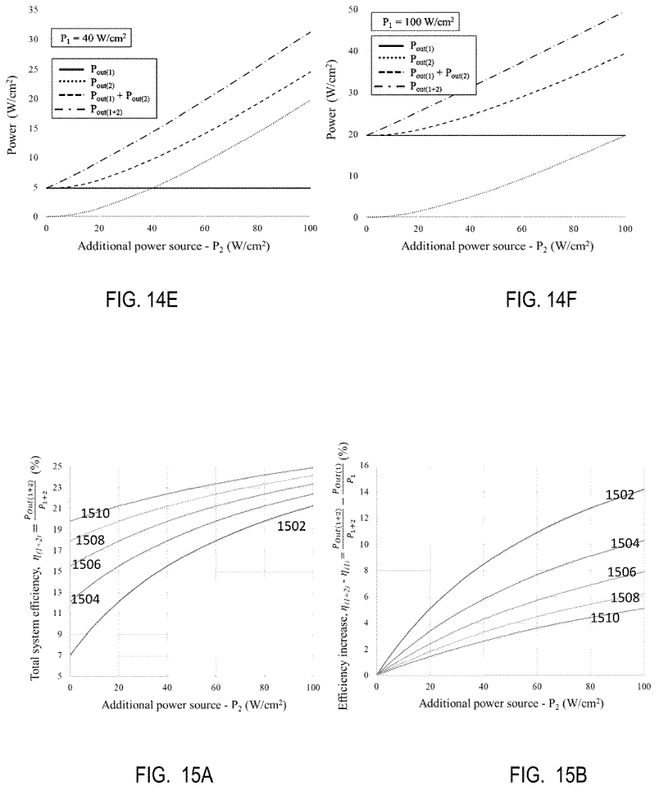

FIG. 14A shows the output power from the TPV system, Pₒᵤₜ₍₁₊₂₎, when it is powered by sources P₁ and P₂ simultaneously as a function of the second power source, P₂, for different values of P₁. In this case the power input to the TPV system is denoted as P₁₊₂.

In FIGS. 14A-c, line 1402 represents 20 W/cm², line 1404 represents 40 W/cm² line 1404 represents 40 W/cm², line 1406 represents 60 W/cm² line 1408 represents 80 W/cm² line 1410 represents 100 W/cm².

FIG. 14B shows the increase in the power output from the TPV system when it is powered by sources 1 and 2 simultaneously (Pₒᵤₜ₍₁₊₂₎) as compared to when it is powered solely by source 1 (Pₒᵤₜ₍₁₎) as a function of the input power from P₂ for different values of P₁.

FIG. 14C shows the sum of the output power for the case when the TPV system is powered solely by source 1 and the case when it is powered solely by source 2 (denoted as Pₒᵤₜ₍₁₎ and Pₒᵤₜ₍₂₎, respectively) as a function of the power received from source 2.

As an example, comparing FIGS. 14A and 14C shows for P₁=P₂=100 W/cm² Pₒᵤₜ₍₁₊₂₎=50 W/cm² and Pₒᵤₜ₍₁₎+Pₒᵤₜ₍₂₎=39.5 W/cm².

Considering another example from FIG. 14A, when P₁=20 W/cm² if the power from the second source is increased from P₂=0 to 20 W/cm² the output power increases from Pₒᵤₜ₍₁₊₂₎=1.39 W/cm² to 4.8 cm² when the power is received from both sources simultaneously. However, as shown in FIG. 14C, when P₁=20 W/cm² and the power from the second source is increased from P₂=0 to 20 W/cm² the sum of the power output from the TPV system when it is powered solely by source 1 and when it is powered solely by source 2 increases from Pₒᵤₜ₍₁₎+Pₒᵤₜ₍₂₎=1.39 W/cm² to 2.8 W/cm². These results demonstrate the benefits and synergistic effects of simultaneously powering TPV systems with a second power source in addition to a beamed power source.

FIGS. 14D, 14E, and 14F show a comparison of the power output from the TPV system when it is powered solely by source 1 (Pₒᵤₜ₍₁₎), when it powered solely by source 2 (Pₒᵤₜ₍₂₎), when it is powered by sources 1 and 2 simultaneously (Pₒᵤₜ₍₁₊₂₎), and the sum of the output power when the TPV system is powered solely by source 1 and solely by source 2 (Pₒᵤₜ₍₁₎+Pₒᵤₜ₍₂₎) for the case when the power received from source 1 is 20, 40, and 100 W/cm², respectively.

FIG. 15A shows the system efficiency when it is powered by sources 1 and 2 simultaneously

$$\\ ( {η}_{( 1 + 2 )} = \frac{{P}_{out ( 1 + 2 )}}{{P}_{1 + 2}} )$$

as a function of the power from the second source, P₂, for different values of P₁. For example, for a first power source of P₁=20 W/cm², by adding a secondary source of P₂=20 W/cm², the system efficiency changes from η₍₁₊₂₎=7 to 12%.

FIG. 15B shows the increase in system efficiency achieved by adding the secondary source as compared to when the TPV system is powered solely by source

$$\\ 1 ( {η}_{( 1 + 2 )} - {η}_{( 1 )} = \frac{{P}_{out ( 1 + 2 )}}{{P}_{1 + 2}} - \frac{{P}_{Out ( 1 )}}{{P}_{1}} ) .$$

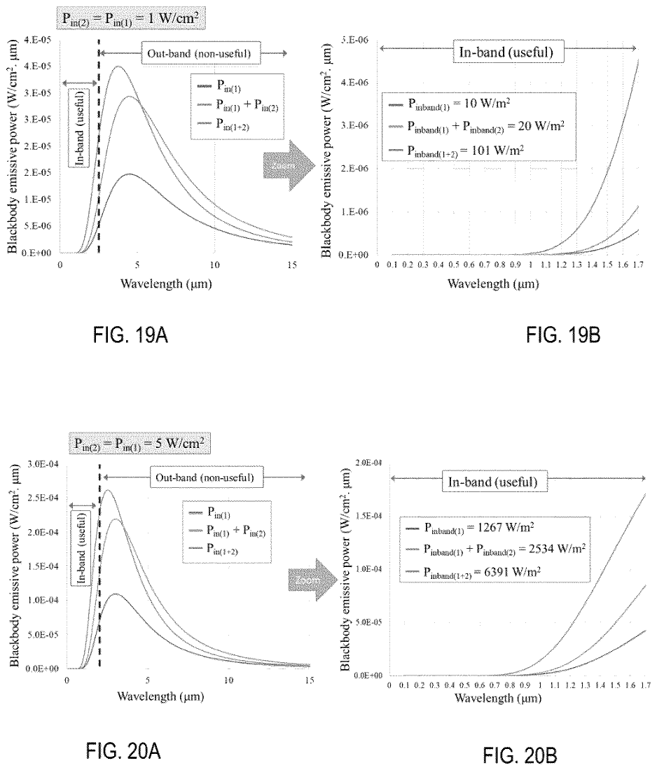

For example, as explained with reference to FIG. 19A, by adding a power source of P₂=20 W/cm² to a TPV system that is already being powered by a source with power equal to P₁=20 W/cm², the net increase of the efficiency is 5.1%.

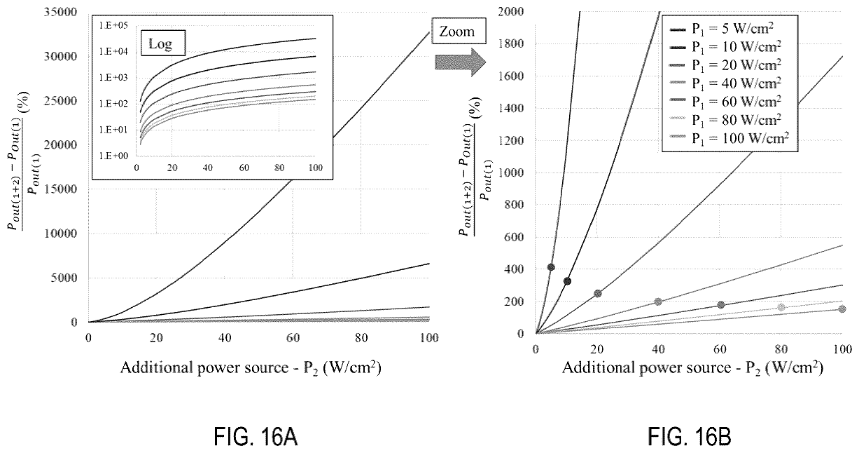

FIG. 16A shows the percentage increase in the output power when the system is powered by two power sources as compared to when it is powered solely by the first power source

$$\\ ( \frac{{P}_{out ( 1 + 2 )} - {P}_{Out ( 1 )}}{{P}_{out ( 1 )}} \times 100 \% ) .$$

The results show that when the first power source, P₁, is small the addition of a relatively small amount of power from a second source, P₂, results in a large percentage increase in the output power. For example, for a constant initial power of P₁=5 W/cm² by adding the second power source of P₂=5 W/cm², the change rate of the output power will be

$$\\ \frac{{P}_{out ( 1 + 2 )} - {P}_{Out ( 1 )}}{{P}_{out ( 1 )}} \times 100 \% = 421 \% .$$

FIG. 16B shows the results in FIG. 16a for increases in power output up to 2000%. For example, as shown by the green dot in FIG. 16b when the first source provides a constant power of P₁=100 W/cm², adding a secondary power source of P₂=100 W/cm² causes the output power to increase by 151%.

In both FIGS. 16A and 16B, the topmost line on the graph represents 5 W/cm² with the each subsequently lower line representing the next highest W/cm², as follows 10 W/cm² 20 W/cm², 40 W/cm², 60 W/cm², 80 W/cm², and 100 W/cm².

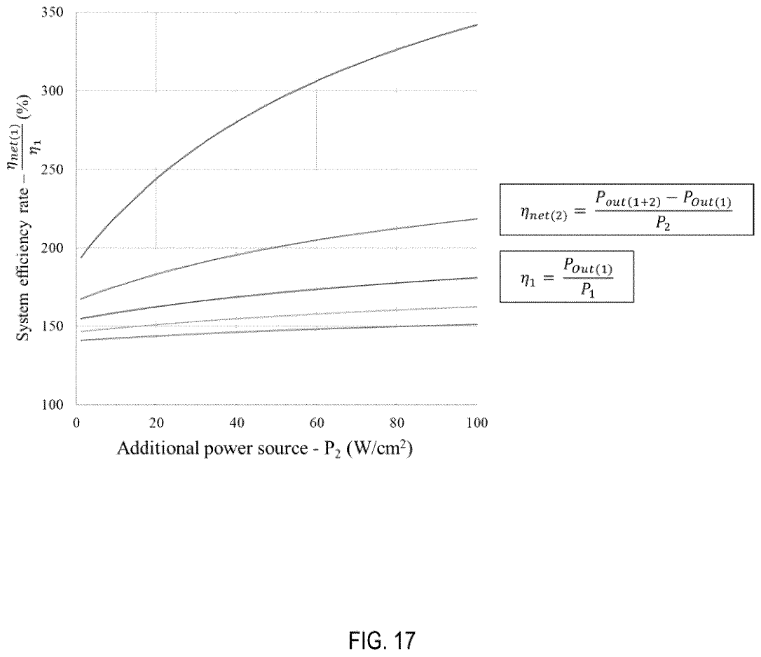

FIG. 17 shows the relative increase in system efficiency when the system is powered by sources 1 and 2 simultaneously as compared to when it is powered solely by source

$$\\ 1 ( {η}_{net ( 2 )} / {η}_{1} = \frac{{P}_{out ( 1 + 2 )} - {P}_{Out ( 1 )}}{{P}_{2}} / \frac{{P}_{Out ( 1 )}}{{P}_{1}} )$$

as a function of P₂. For example, supplying the TPV system with a second source of power of P₂=20 W/cm² when it is already powered from a first power source of P₁=20 W/cm², causes the TPV system conversion efficiency to increase by 244%.

Not all W/cm² are shown in FIG. 17. The top line represents 20 W/cm², the next line down represents 40 W/cm², the next line down represents 60 W/cm², the next line down represents 80 W/cm², and the bottom line represents 100 W/cm².

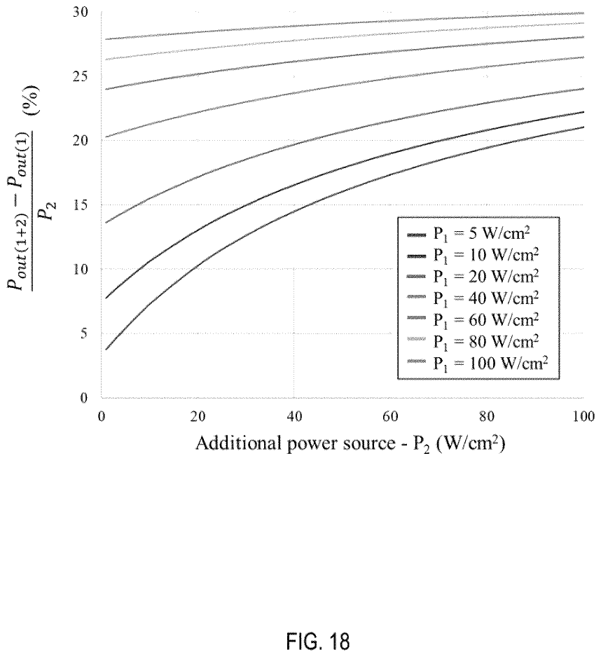

FIG. 18 shows the efficiency with which the additional power (P₂) is converted to electric power when it is added to TPV system that is already powered by an initial power source (P₁) as a function of P₂.

The bottom most line on the graph represents 5 W/cm², with the each subsequently higher line representing the next highest W/cm², as follows 10 W/cm², 20 W/cm², 40 W/cm², 60 W/cm², 80 W/cm², and the top line representing 100 W/cm².

The results reported in FIGS. 8A through 18 can be improved by reducing radiative heat losses from the emitter. This can be accomplished by reducing the physical dimensions of the absorber and emitter. If the size of the absorber/emitter is reduced, then the beam diameter or spot size of the incident electromagnetic radiation may also need to be reduced to ensure it radiates the absorber.

FIG. 19 shows the blackbody emissive power of an emitter when the input heat power for the primary and secondary sources are the same at Pᵢₙ₍₁₎=Pᵢₙ₍₂₎=1 W/cm². FIG. 19A shows the blackbody emissive power for three cases of Pᵢₙ₍₁₎ (or Pᵢₙ₍₂₎), Pᵢₙ₍₁₎+Pᵢₙ₍₂₎, and Pᵢₙ₍₁₊₂₎. The bottom line represents Pᵢₙ₍₁₎, the middle line represents Pᵢₙ₍₁₎+Pᵢₙ₍₂₎, and the top line represents Pᵢₙ₍₁₊₂₎. The vertical dashed line shows the bandgap of the GaSb PV cell assumed as the PV cell in this study (e.g., =1.72 μm). FIG. 19B shows a closer view of the blackbody emissive power for the in-band region (the region photons have higher energy than the bandgap energy of the GaSb PV cell and can be converted to electricity. FIG. 19B shows that each power source generates P_{inband(1)}=P_{inband(2)}=10 W/m² (0.0001 W/cm²) of in-band power, but when both of them are combined, the total in-band power reaches 101 W/m² means almost 500% of the individually applied heat sources.

FIG. 20 is similar to FIG. 19 but Pᵢₙ₍₁₎=Pᵢₙ₍₂₎=5 W/cm². As can be seen, each power source generates in-band power of P_{inband(1)}=P_{inband(2)}=1267 W/m2 (~0.13 W/cm2). But when both of them are combined, the total in-band power reaches 6391 W/m2 means almost 250% of the individually applied heat sources. The bottom line represents Pᵢₙ₍₁₎, the middle line represents Pᵢₙ₍₁₎+Pᵢₙ₍₂₎, and the top line represents Pᵢₙ₍₁₊₂₎. The vertical dashed line shows the bandgap of the GaSb PV cell assumed as the PV cell in this study (e.g., =1.72 μm).

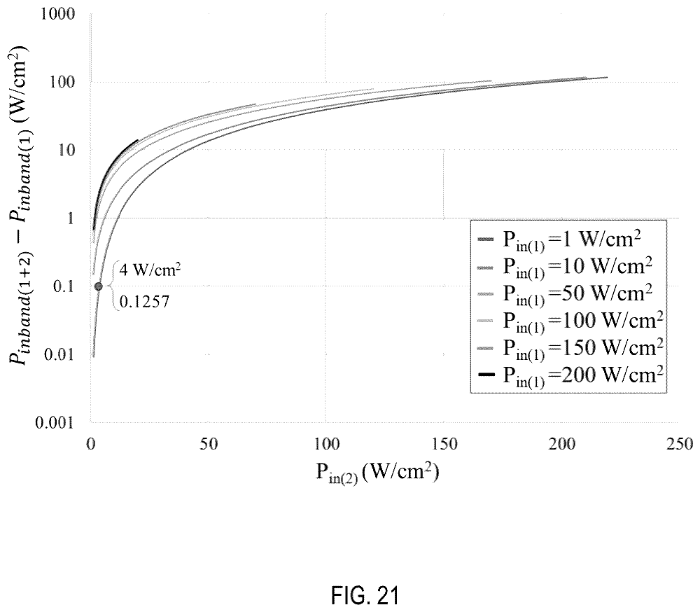

FIG. 21 shows the net output in-band power (in-band power delivered to the GaSb PV cell) when the output in-band power of the primary source applied to the system (P_{inband(1)}) is subtracted from the total output in-band power when both sources are applied simultaneously (P_{inband(1+2)}) as a function of the secondary power input (Pᵢₙ₍₂₎), for six sample examples of primary/initial input power sources to the multisource TPV system. In this analysis the maximum total power applied to the system is 220 W/cm². For example, as seen in this figure, when the secondary power source of Pᵢₙ₍₂₎=4 W/cm², is applied to the TPV system with initially running by Pᵢₙ₍₁₎=1 W/cm², the net in-band power due to applying the second source is P_{inband(1+2)}−P_{inband(1)}=0.1257 W/cm².

The bottom most line on the graph of FIG. 21 represents 1 W/cm², with the each subsequently higher line representing each next highest W/cm², 10 W/cm², 50 W/cm², 100 W/cm² 150 W/cm², and the top line representing 200 W/cm².

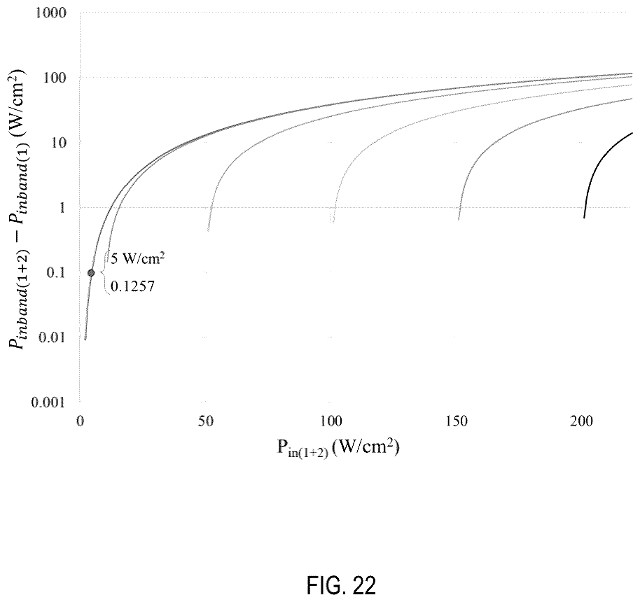

Similarly, FIG. 22 shows the net output in-band power when the output in-band power of the primary source applied to the system (P_{inband(1)}) is subtracted from the total output in-band power when both sources are applied simultaneously (P_{inband(1+2)}) as a function of the summation of the primary and secondary power input applied simultaneously (Pᵢₙ₍₁₊₂₎), for six sample examples of primary/initial input power sources to the multisource TPV system. For example, as seen in this figure, when the secondary power source of Pᵢₙ₍₂₎=4 W/cm², is applied to the TPV system with initially running by Pᵢₙ₍₁₎=1 W/cm² (Pᵢₙ₍₁₊₂₎=5 W/cm²), the net in-band power due to applying the second source is P_{inband(1+2)}−P_{inband(1)}=0.1257 W/cm².

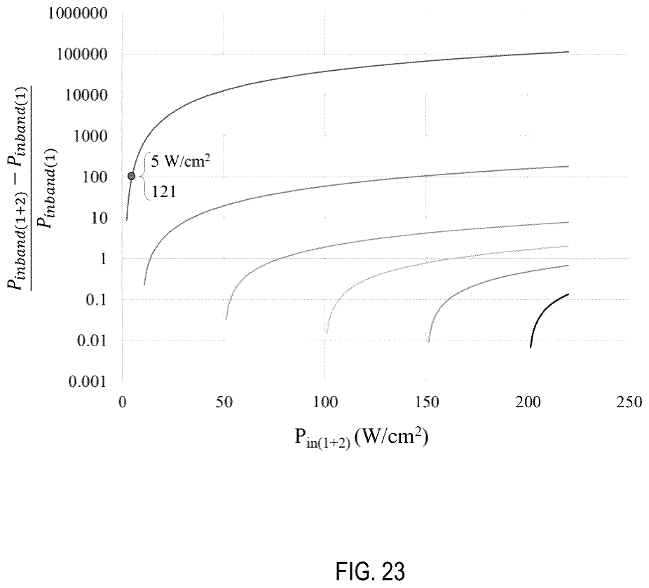

FIG. 23 shows the ratio of the in-band power as a result of adding the secondary source over the in-band power when only primary source is applied

$$\\ ( \frac{{P}_{inband ( 1 + 2 )} - {P}_{inband ( 1 )}}{{P}_{inband ( 1 )}} ) .$$

For example, when the primary source of Pᵢₙ₍₁₎=1 W/cm² and the secondary source of Pᵢₙ₍₁₎=4 W/cm² are applied to the system simultaneously (Pᵢₙ₍₁₊₂₎=5 W/cm²), the net in-band power delivered to the GaSb PV cell as a result of adding the secondary source increases by 121 times (%12,100).

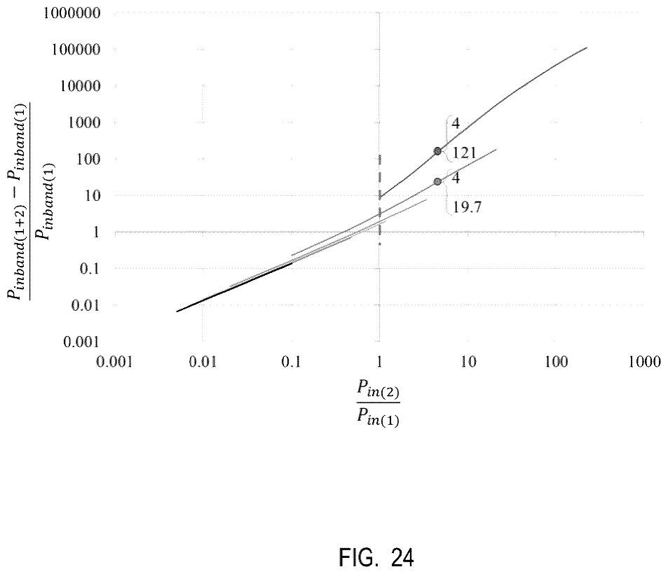

Similarly, FIG. 24 shows the ratio of the in-band power as a result of adding the secondary source, over the in-band power when only primary source is applied

$$\\ ( \frac{{P}_{inband ( 1 + 2 )} - {P}_{inband ( 1 )}}{{P}_{inband ( 1 )}} )$$

as a function of the ratio of the secondary source to primary source

$$\\ ( \frac{{P}_{in ( 2 )}}{{P}_{in ( 1 )}} ) .$$

For example, when the primary source of Pᵢₙ₍₁₎=1 W/cm² and the secondary source of Pᵢₙ₍₁₎=4 W/cm² are applied to the system simultaneously

$$\\ ( \frac{{P}_{in ( 2 )}}{{P}_{in ( 1 )}} = 4 ) ,$$

the net in-band power delivered to the GaSb PV cell as a result of adding the secondary source increases by 121 times (%12,100). As another example, when the primary source of Pᵢₙ₍₁₎=10 W/cm² and the secondary source of Pᵢₙ₍₁₎=40 W/cm² are applied to the system simultaneously

$$\\ ( \frac{{P}_{in ( 2 )}}{{P}_{in ( 1 )}} = 4 ) ,$$

the net in-band power delivered to the GaSb PV cell as a result of adding the secondary source increases by 19.7 times (%1,970).

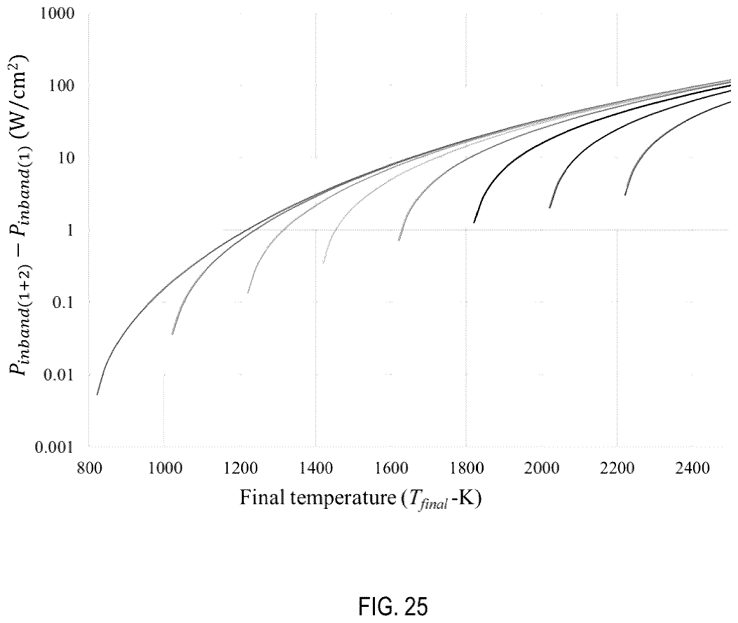

The output power of a TPV system is mainly a function of power emitted from the surface of the emitter, and the temperature of the emitter. In FIGS. 25 to 27 the system evaluation of the multisource TPV system is based on the primary temperature of the emitter surface (T₁) due to the primary source and the temperature of the emitter surface (T₂) due to the secondary source. In these studies, the emitter is a blackbody (ε=1).

FIG. 25 shows the net output in-band power (in-band power delivered to the GaSb PV cell) when the output in-band power of the primary source applied to the system (P_{inband(1)}) is subtracted from the total output in-band power when both sources are applied simultaneously (P_{inband(1+2)}) as a function of the final temperature of the emitter when both sources are applied simultaneously (T_{final}), for eight sample temperatures of the emitter due to the primary source. The maximum temperature on the emitter surface due to the applied sources is limited to 2500 K.

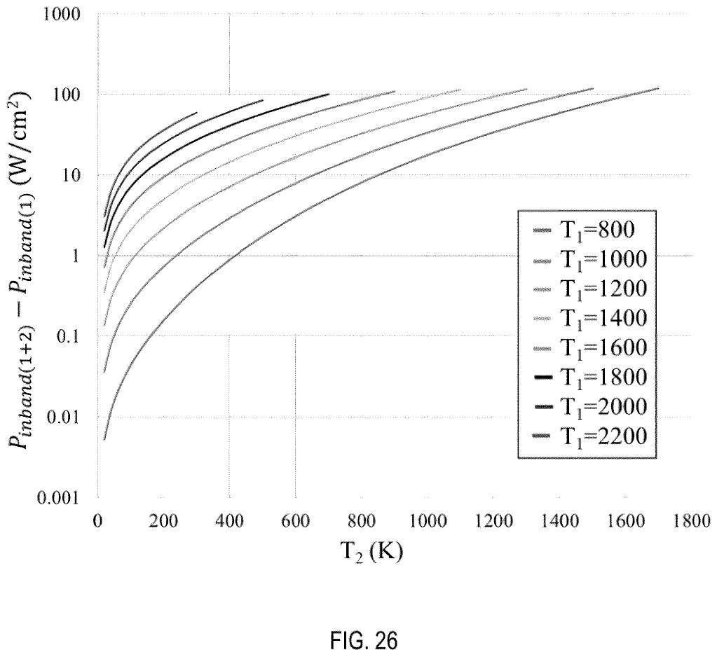

Similarly, FIG. 26 shows the net output in-band power (in-band power delivered to the GaSb PV cell) when the output in-band power of the primary source applied to the system (P_{inband(1)}) is subtracted from the total output in-band power when both sources are applied simultaneously (P_{inband(1+2)}) as a function of the temperature of the emitter when the secondary source is applied (T₂), for eight sample temperatures of the emitter due to the primary source.

The bottom line represents a T₁ of 800K, with each subsequent higher line representing initial temperatures of 1000K, 1200K, 1400K, 1600K, 1800K, 2000K, and 2200K.

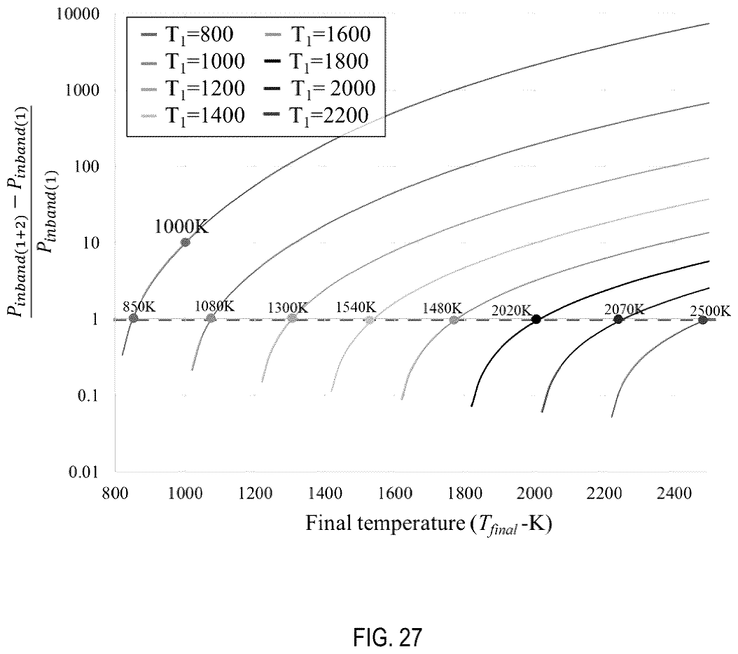

FIG. 27 shows the ratio of the in-band power as a result of adding the secondary source, over the in-band power when only primary source is applied

$$\\ ( \frac{{P}_{inband ( 1 + 2 )} - {P}_{inband ( 1 )}}{{P}_{inband ( 1 )}} )$$

as a function of the final surface temperature of the emitter when both sources are applied simultaneously, for eight samples of the emitter temperature due to the primary source. For example, the emitter has a temperature of T₁=800 K (due to the primary source) and the secondary source increase the temperature of the emitter by T₂=50 K (T_{final}=850 K). The net in-band photons delivered to the GaSb PV cell due to the adding that 50 K, is the same as the amount of the net in-band power delivered to the PV cell when the secondary source had not been applied

$$\\ ( \frac{{P}_{inband ( 1 + 2 )} - {P}_{inband ( 1 )}}{{P}_{inband ( 1 )}} = 1 ) .$$

As another example, when the temperature of the emitter due to the primary source is T₁=800 K, applying the secondary source to increase the emitter temperature by T₂=200 to T_{final}=1000 K, increases the net in-band power delivered to the GaSb PV cell by 10 times (%1,000).

The left side line represents a T₁ of 800K, with each subsequent line to the right representing initial temperatures of 1000K, 1200K, 1400K, 1600K, 1800K, 2000K, and 2200K.

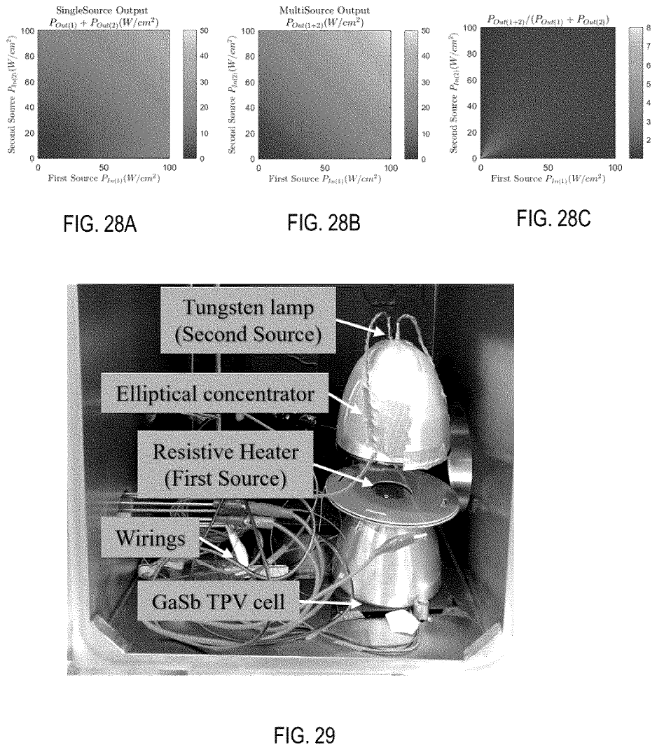

FIG. 28A depicts the theoretical output power of the GaSb PV cell as functions of the primary and secondary heat source ranging from 0 to 100 W/cm² when the input sources are applied separately and then output powers are summed (Pₒᵤₜ₍₁₎+Pₒᵤₜ₍₂₎). On the other hand, FIG. 28B shows the output electric power as functions of the primary and secondary sources when they are applied simultaneously (Pₒᵤₜ₍₁₊₂₎). For example, when the primary and secondary heat sources are both 50 W/cm², the summation of the output power from the sources applied separately is Pₒᵤₜ₍₁₎+Pₒᵤₜ₍₂₎=13.7 W/cm², and Pₒᵤₜ₍₁₊₂₎=19.5 W/cm² when they are applied simultaneously. This result shows a 42% more power output. Finally, FIG. 28C provides the ratio of utilizing a multi-source TPV system to the single-source situation. As shown, for small amounts of input powers, the change rate between Pₒᵤₜ₍₁₎+Pₒᵤₜ₍₂₎ and Pₒᵤₜ₍₁₊₂₎ increases up to 800%.

FIG. 29 shows one sample of the experimental setup for studying the multi-source TPV system. A ceramic resistive heater serves as the first source, while a high-wattage Tungsten light, concentrated by an elliptical concentrator, acts as the second source. The setup, conducted in a vacuum, monitors the emitter temperature and output power changes for different input powers. The experiment progresses where the ceramic heater and light bulb individually increase surface temperature. Then both sources operate simultaneously.

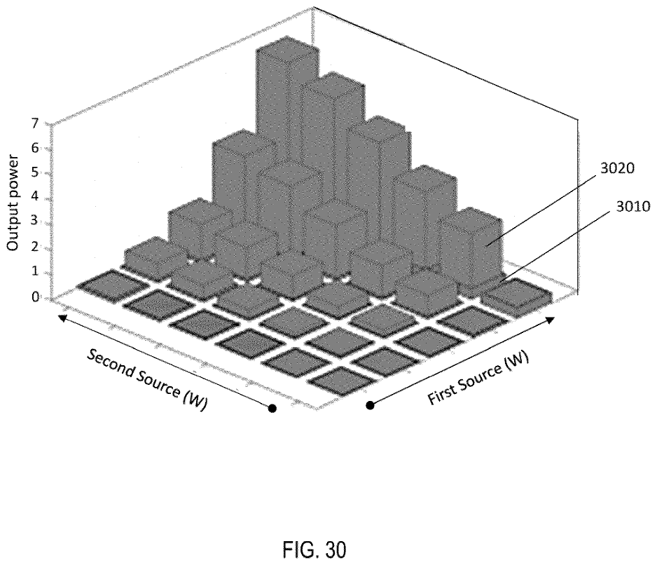

FIG. 30 shows the experimental results where the outer pillars 3010 indicate the electric output based on the single-source mode (Pₒᵤₜ₍₁₎+Pₒᵤₜ₍₂₎) and the inner pillars 3020 are the output power for the multi-source mode (Pₒᵤₜ₍₁₊₂₎) for the multisource TPV system shown in FIG. 29. The first and second sources increase in the direction of the respective arrows.

The above figures represent experimental results for specific embodiments of TPV systems. Aspects of other possible embodiments or implementations are discussed below.

In an embodiment, the emitter may be a solid, liquid, gas, plasma, and/or Bose-Einstein condensates, and/or other state of matter or a combination thereof.

In some embodiments, systems and methods are used for communication receivers and transmitters. Receivers may include one or more of the following: traditional antenna, laser communication, atomic electrometry (e.g. Rydberg atoms), or the like, and or a combination thereof. Transmitters, use radiative and non-radiative methods for power transmission. Atomic electrometry and or the like may be used in some implementations. In some embodiments, wireless power transmission may be used.

In some embodiments, methods incorporate analog and digital electromagnetic signals, detection, and imaging applications, and may use cold and/or hot Rydberg atoms. Other methods include using mixers, such as atomic mixer to enhance the target signal.

In some embodiments, TPV systems and methods are used for application on Earth (land, sea, and/or air).

In some embodiments, TPV systems and methods are used for applications in Space.

In some embodiments, various fuels can be used to provide heat for the conversion. In other examples, metallic fuels can be used, which may include: metals, metal alloys, micro and/or nano energetic particles. In other embodiments, recyclable fuels may be used.

In some embodiments, TPV systems may be incorporated and/or coupled with one or more other power/heat generating systems and methods to generate electricity.

In some examples, various fuels such as metals and metallic alloys may be sourced from Earth. In other examples, sources may include recycling space debris, retired satellites in orbit, second stages, empty fuel tanks, or other materials transported from Earth to space. In other examples, metal and metal alloys may be sourced from space. Sources may also include materials from the Mars (Martian regolith), asteroid sources, planetoids, other celestial bodies, or a combination thereof.

In some embodiments, fuels may be heated and/or undergo combustion.

In some embodiments, TPV systems may be used to power a mobile/fixed system operating in/on Land, Air, Water, and/or Space.

In some embodiments, a plurality of power distribution networks and topology methods may be used to share power in between and among a plurality of mobile systems.

In some embodiments, semi-autonomous and/or autonomous systems and methods may be incorporated. Remote operations may be enabled using TPV systems.

In some embodiments, systems and methods may be deployed in a plurality of smart cities and/or infrastructure to generate electricity.

In some embodiments, a plurality of reflectors may be used.

In some embodiments, one of the sources used to power a TPV system may be an incident electromagnetic beam from a laser.

In some embodiments, one of the sources used to power a TPV system may be inductive-couple and/or magnetically coupled systems using primary and secondary coils to vary the magnetic fields to drive heating, sintering and combustion processes and/or applications.

In some embodiments, the thermophotovoltaic (TPV) cell or photovoltaic (PV) cell may be in different shapes and configurations.

In some embodiments, a source used to power the TPV system may be an incident electromagnetic beam from a maser (i.e., Microwave Amplification by Stimulated Emission of Radiation).

In some embodiments, microwave collimators including Cassegrain-, Horn-, Lens-, Dielectric Lens-, and Reflective Lens antennas, may be used to transmit an electromagnetic beam to the TPV system to be used as a power source.

In some embodiments a negative-index-of-refraction lens may be used to collimate an electromagnetic beam incident onto the TPV system.

In some embodiments, a microwave concentrator, including planar and hyperbolic lenses, may be used to focus incident microwaves onto the TPV system.

In some embodiments, metamaterials may be used to collimate and/or concentrate an electromagnetic beam incident onto the TPV system.

In some embodiments, the power beam may be delivered as an electromagnetic pulse or as a periodically pulsed electromagnetic beam.

In some embodiments, TPV systems and methods may be used to augment operations.

In some embodiments, TPV systems and methods may be used on satellites and rovers.

In some embodiments, TPV systems and methods may be used for power generation and/or solar/natural gas power systems as an output.

In some embodiments, TPV systems and methods may be integrated central receiver concentrators, linear, and/or parabolic dish concentrators and/or other types of concentrators.

In some embodiments, micro-channel and mesh-channel chemical process receivers are used.

In some embodiments, TPV systems and methods may include filters, such as optical filters. Filters might be composed of layers of nanoparticles and/or microparticles. Layers within the filter may be a plurality of shapes and compositions to optimize TPV systems and methods.

In some embodiments, filters used in TPV systems and methods may be additively manufactured.

In some embodiments, advanced combined cycle power systems are used in co-generation and/or multi-generation purposes.

In some embodiments, TPV systems and methods may be used to heat or sinter materials on Earth and/or space.

In some embodiments, TPV systems and methods may be used in solar thermal/solar thermochemical processes to help drive reactions.

In some embodiments, TPV systems and methods may be used to produce fuel and/or pre-heat fuel.

Possible applications of the various implementations of a TPV system include: the combustion of the product syngas (i.e., synthetic gas) in a hybrid, solar/natural gas power plant, providing an efficient solar augment to the natural gas fuel; the thermochemical storage of the solar energy as part of an open or closed-cycle storage process; combined cycles; the production of the hydrogen or the like for use in fuel cells and for other purposes; and the production of synthetic fuels such as methanol or long chain hydrocarbons; materials for storage systems; storage systems.

In some embodiments, TPV systems and methods may be used for on-demand energy production and/or catalyst driven applications.

In some embodiments, TPV systems and methods may use Fresnel lens for the receiver and transmitter.

In some embodiments, TPV systems and methods are used for de-orbiting satellite systems.

In some embodiments, TPV systems and methods can be used to recharge a fleet of systems or vessels to increase operation and performance in harsh environments where sunlight is limited or not available. For example, multi-source TPV systems are equipped onto multi-layered constellation, and the constellation is recharged using a plurality of transmitters to generate power and/or propulsion. In other implementation, a plurality of transmitters may be used.

In some embodiments, TPV systems can be attached to space debris, to power generation and distribution, and propulsion and/or debris removal purposes.

In some embodiments, TPV systems and methods may be incorporated into other byproducts and/or multi-fuel generation applications to create fuels such as metallic fuels, metals, alloys, nano and micro-composites, additive hydrogen, ammonia, syngas, or the like.

In some embodiments, TPV systems and methods may be used in in situ resource utilization.

In some embodiments, TPV systems and methods may be integrated with at least one of: instruments and machines, components, systems in heavy industries, mining applications, consumer products and services, in space applications, in situ resource utilization and/or in situ resource processing on the Moon, Mars, asteroids, or other celestial bodies, in space habitats and other space architecture, in space analogous, remote locations, and other extreme environments.

In some embodiments, TPV systems and methods may be integrated into heat engines.

In some embodiments, TPV systems and methods may be for mobile vehicles operating on Land, Air, Water, and Space, including but not limited to drones, airships, submarines, aircraft, watercraft, spacecraft, space systems, space architecture or the like.

In some embodiments, TPV systems and methods may be fixed or mobile.

In some embodiments, TPV systems and methods may be used in combined power and propulsion cycles.

In some embodiments, TPV systems and methods may be used in cogeneration, trigeneration, distributed and/or other multigeneration systems or the like, or methods for heating and cooling.

In some embodiments, TPV systems and methods for multigeneration systems and/or other multi-source integrated energy systems.

In some embodiments, origami systems and methods may be used to implement TPV systems.

In some embodiments, the multi-source TPV may be used as a processing, furnace and/or recycling system to receive materials, for heating materials to high temperatures through controlled thermal processes to create useful byproducts. The multisource TPV system may be configured with a combustion chamber, where materials may be heated to drive reactions and/or heat materials to a high temperature, the byproducts are then directed to a set of compartments in which different materials could be stored. For recycling applications, materials to be recycled may be directed to the combustion chamber coupled with the multisource TPV system for heating purposes, where materials are heated and processed, after which byproducts are directed to a set of compartments for storage. Also, reflectors may be used to concentrate the solar energy to heat the combustion chamber, and/or directed energy may be used to increase the heat generation, and the TPV system is used to ensure a constant temperature is maintained in the combustion chamber. In other implementations, the combustion chamber coupled with TPV system may be used to recycle space debris or process space resources for space applications.

In some embodiments, byproducts from the recycling of materials using the multisource TPV may be used as feedstock for fuel production and/or to support applications for in-orbit servicing, assembly, and manufacturing.

In some embodiments, a cooling system may be integrated with the multi-source TPV for thermal control. Furthermore cooling systems may include one or more of the following: vapor-compression cycles through cycles of evaporation and condensation, evaporative cooling (e.g. evaporation of water to absorb the heat, cooling the air), radiative cooling, heat sinks, heat pipe or loop heat pipes using phase change and capillary action to transport heat away from sensitive components, fluid loops to circulate coolant fluids through heat exchangers and radiators, thermoelectric coolers such as Pelletier devices, multi-layer insulation where layer of reflective materials are separated by spacers to reduce heat transfer, and/or phase change materials where excess heat is absorbed to change a phase change (e.g. solid to liquid) or the like.

In some embodiments, the multi-source TPV system may be used as furnace for example, to operate as a blast furnace, electric arc furnace, induction furnace, reverberatory furnace, cupola furnace, solar furnace, combustion furnace, rotary kiln, and/or electric resistance furnace or the like.

In some embodiments, TPV systems and methods may be used for thermal energy storage. Furthermore, the thermal energy storage may be used to support applications to be used in rural regions and/or in smart cities.

In some embodiments, the use of a laser creates the conditions in an atmosphere for a conductor type column, which allows for optimal energy transfer from a co-linear electromagnetic beam. Various distribution methods between the 2 sources of energy transmitted from point to point, to a plurality of nodes. In other examples, a maser or the electromagnetic source may be used to create the initial conditions, to enable another source of electromagnetic radiation to be co-transmitted. Power distribution P2P to a plurality of receiving nodes may be transferred using a plurality of transmitters.

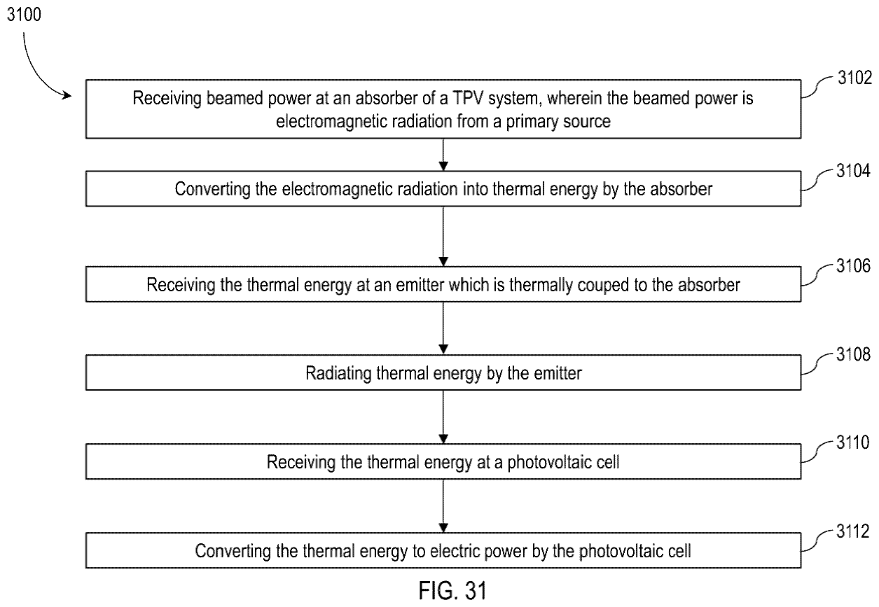

FIG. 31 is a flow diagram of a method of using a multisource-capable TPV system.

At 3102, an absorber of a multisource capable TPV system receives beamed power (or similar type of electromagnetic radiation) from a primary source.

At 3104, the absorber converts the electromagnetic radiation from the beamed power into thermal energy.

At 3106, an emitter which is thermally coupled to the absorber receives the thermal energy from the absorber.

At 3108, the emitter radiates or emits the thermal energy,

At 3110, a (thermo)photovoltaic cell (PV) receives the thermal energy from the emitter.

At 3112, the TPV converts the thermal energy to electric power (energy).

As described above, various systems may include various configurations of TPV system. Some TPV systems may include an optical cavity which may be an ellipsoid or spheroid shape. The optical cavity serves to concentrate the electromagnetic radiation. Some TPV systems may include optical filters or mirrors for filtering and directing electromagnetic radiation.

In other embodiments, the absorber may absorb further energy from at least one secondary source. The energy provided by the at least one secondary source may be electromagnetic radiation, heat from combustion of fuel, waste heat, solar irradiance, heat from nuclear reactions, etc. Any number of sources and type of energy can be used as long as the energy can be converted to electric power by an absorber, emitter, and PV cell. For example, beamed power and heat may be received simultaneously to heat the absorber and the emitter within the TPV system.

The beamed power may be electromagnetic waves over a broad spectrum, including wavelengths from the X-ray to radio waves.

The absorber may receive the same type of energy from more than one source. For example, the absorber may receive beamed power from at least two sources.

A temperature of the thermally coupled absorber and emitter is greater when heated by multiple sources than the temperature of the thermally coupled absorber and emitter when heated by each of the multiple sources individually.

In some embodiments the PV cell may directly receive electromagnetic radiation from the primary source and the emitter may receive energy from the at least one secondary source.

In some embodiments the absorber and the emitter may be connected to a thermal battery which stores thermal energy.

As described above, the advantages of a multisource TPV system are many. The integration of multiple heat sources to power a TPV system significantly enhances system output and efficiency. Through both numerical and experimental analysis, it is shown that simultaneous operation of dual heat sources leads to a notable increase in output power—up to 42% more compared to single-source operations when both sources are Pin=50 W/cm2. The enhancement is particularly pronounced at lower input power levels, highlighting the potential for substantial efficiency gains in low-temperature applications. The ability to harness and effectively manage multiple heat sources not only broadens the applicability of TPV systems across various thermal sources but also paves the way for more cost-effective and scalable energy solutions.

While the above description provides examples of one or more apparatus, methods, or systems, it will be appreciated that other apparatus, methods, or systems may be within the scope of the claims as interpreted by one of skill in the art.

1. A multisource capable thermophotovoltaic (TPV) system for converting electromagnetic energy to electric power, the system comprising:
an absorber that receives directed energy in the form of electromagnetic radiation from at least a primary source and converts the electromagnetic radiation to thermal energy;
an emitter, thermally coupled to the absorber, wherein the emitter receives the thermal energy from the absorber and radiates the thermal energy; and
a photovoltaic cell which receives the thermal energy from the emitter and converts the thermal energy to electric power.

2. The TPV system according to claim 1, wherein the directed energy is electromagnetic waves over a broad spectrum, including wavelengths from the X-ray to radio waves.

3. The TPV system of any one of claims 1 to 2, wherein the absorber receives energy from at least a secondary source.

4. The TPV system of claim 3, wherein the absorber receives heat from the at least a secondary source.

5. The TPV system of any one of claims 3 to 4, wherein the at least a secondary source provides energy from one of fuel combustion, concentrated solar irradiance, waste heat, and heat from nuclear sources.

6. The TPV system of claim 4, wherein the directed energy and the heat are received simultaneously to heat the absorber and the emitter within the TPV system.

7. The TPV system of any one of claims 1 to 6, wherein the absorber receives directed energy from at least two sources.

8. The TPV system of any one of claims 1 to 7, wherein a temperature of the thermally coupled absorber and emitter is greater when heated by multiple sources than the temperature of the thermally coupled absorber and emitter when heated by each of the multiple sources individually.

9. The TPV system of any one of claims 1 to 8, wherein the PV cell directly receives electromagnetic radiation from the primary source and the emitter receives energy from the at least one secondary source.

10. The TPV system of claim 9, wherein the energy of the at least one secondary source is one of fuel combustion, concentrated solar irradiance, waste heat, heat from nuclear sources, and another directed energy.

11. The TPV system of any one of claims 1 to 10, wherein the absorber and the emitter are connected to a thermal battery.

12. The TPV system of any one of claims 1 to 11 further comprising an optical cavity to concentrate electromagnetic radiation.

13. The TPV system of claim 12, wherein the optical cavity has an oblate ellipsoid shape.

14. The TPV system of claim 12 wherein the optical cavity has an oblate hemispheroid shape.

15. The TPV system of any one of claims 1 to 14 further comprising an optical filter.

16. A method of converting electromagnetic radiation to electric power, the method comprising:
receiving, by an absorber, directed energy in the form of electromagnetic radiation from at least a primary source;
converting the electromagnetic radiation to thermal energy, by the absorber;
receiving, by an emitter thermally coupled to the absorber, the thermal energy;
radiating the thermal energy, by the emitter;
receiving the thermal energy by a photovoltaic cell; and
converting the thermal energy to electric power by the photovoltaic cell.

17. The method of claim 16, wherein the absorber receives energy from at least a secondary source.

18. The method of claim 17, wherein the absorber receives heat from the at least a secondary source.

19. The method of claim 17, wherein the directed energy and the heat are received simultaneously to heat the absorber and the emitter within the TPV system.

20. The method of any one of claims 16 to 19, wherein a temperature of the thermally coupled absorber and emitter is greater when heated by multiple sources than the temperature of the thermally coupled absorber and emitter when heated by each of the multiple sources individually.
